(19) United States
(12) Patent Application Publication
(10) Pub. No.: US 2026/0033318 A1
(43) Pub. Date: Jan. 29, 2026

(54) MEMORY DEVICE INCLUDING CONDUCTIVE CONTACTS WITH MULTIPLE LINERS

(71) Applicant: Micron Technology, Inc., Boise, ID (US)

(72) Inventors: Matthew J. King, Boise, ID (US); Sidhartha Gupta, Boise, ID (US); Terry Hyunsik Kim, Boise, ID (US)

(21) Appl. No.: 19/275,584

(22) Filed: Jul. 21, 2025

Related U.S. Application Data
(60) Provisional application No. 63/676,738, filed on Jul. 29, 2024.

(51) Int. Cl. H01L 23/528; G11C 5/06; H01L 21/768; H01L 23/532; H10B 41/27; H10B 41/35; H10B 41/41; H10B 43/27; H10B 43/35; H10B 43/40

(52) U.S. Cl. CPC H01L 23/528; G11C 5/063; H01L 21/76831; H01L 21/76877; H01L 23/5283; H01L 23/53295; H10B 41/27; H10B 41/35; H10B 41/41; H10B 43/27; H10B 43/35; H10B 43/40

(57) ABSTRACT

Some embodiments include apparatuses and methods of forming the apparatuses. One of the apparatuses includes levels of dielectric materials interleaved with levels of conductive materials, the levels of conductive materials including a first conductive level and a second conductive level; a memory cell string including a pillar extending in a direction from the first conductive level to the second conductive level, the second conductive level including a side wall; a conductive contact extending in the direction from the first conductive level to the second conductive level and contacting the second conductive level; a first dielectric material between the first conductive level and the conductive contact, the first dielectric material having a first dielectric constant; and a second dielectric material between the first dielectric material and the conductive contact, the second dielectric material having a second dielectric constant, wherein the second dielectric constant is greater than the first dielectric constant.

### PRIORITY APPLICATION

This application claims the benefit of priority to U.S. Provisional Application Ser. No. 63/676,738, filed Jul. 29, 2024, which is incorporated herein by reference in its entirety.

### BACKGROUND

Dimensions of structures of some of the components in a memory device are relatively small (e.g., in nanometer size). A memory device (e.g., a flash memory device) has control gates and associated conductive contact structures to provide control signals (e.g., word line signals) to control access to memory cells of the memory device. The conductive contact structures are electrically isolated from other conductive structures to maintain proper memory operation of the memory device. At a certain small dimension of some memory devices, it can be a challenge to maintain proper electrical isolation associated with conductive contact structures in such memory devices.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3A shows a detailed schematic diagram of two blocks of the memory device of FIG. 2, according to some embodiments described herein.

FIG. 3B shows an example of the memory device of FIG. 3A including multiple drain select gates, according to some embodiments described herein.

FIG. 4 shows a top view of a structure of a portion of the memory device of FIG. 3 including a region of a memory array, a conductive contact region, and structures between the blocks of the memory device, according to some embodiments described herein.

FIG. 5A shows a side view (e.g., cross-section) of a structure of a portion of the memory device of FIG. 4, including tiers of materials that include respective memory cells and control gates associated with the memory cells, according to some embodiments described herein.

FIG. 5B shows a variation of the memory device of FIG. 5A, including a memory cell pillar associated with multiple drain select gates, according to some embodiments described herein.

FIG. 6A, FIG. 6B, and FIG. 6C show top views of respective portions of the structure of the memory device of FIG. 4 and FIG. 5A, including conductive contacts and dielectric structures (e.g., support structures), according to some embodiments described herein.

FIG. 7A and FIG. 7B show side views (e.g., cross-sections) of a portion of the memory device of FIG. 6A and FIG. 6B, including conductive contacts and dielectric structures, according to some embodiments described herein.

FIG. 7C shows a top view (e.g., cross-section) at location 7C of the memory device of FIG. 7B.

FIG. 8A shows a memory device that can be a variation of the memory device of FIG. 7A and FIG. 7B, according to some embodiments described herein.

FIG. 8B shows a top view (e.g., cross-section) at location 8B of the memory device of FIG. 8A.

FIG. 9 shows a memory device that can be a variation of the memory device shown in FIG. 6A, according to some embodiments described herein.

FIG. 10A through FIG. 24 show different views of elements during processes of forming a memory device including forming conductive contacts of the memory device, according to some embodiments described herein.

FIG. 25 through FIG. 28 show different views of elements during processes of forming another memory device including forming conductive contacts of the memory device, according to some embodiments described herein.

### DETAILED DESCRIPTION

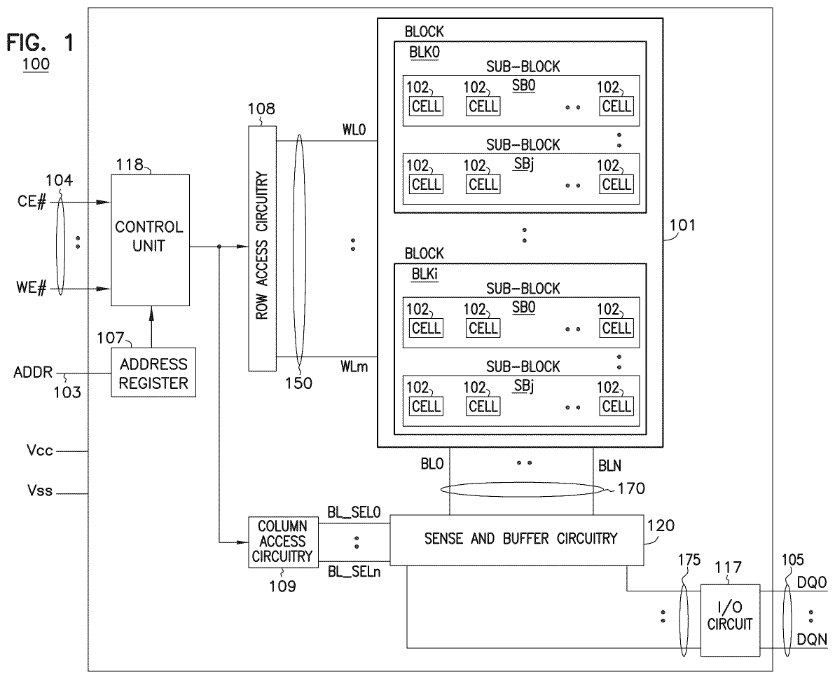

The techniques described herein involve a memory device including memory cells formed in tiers (different physical levels) of the memory device. The tiers include respective levels of conductive materials. The conductive materials form part of control gates (e.g., word lines) associated with the memory cells. The described memory device includes conductive contacts associated with the control gates. The conductive contacts have pillar structures extending through the tiers. As described in more detail below, the techniques described herein provide an electrical isolation structure that includes multiple dielectric materials (e.g., dielectric liners) between a respective conductive contact and adjacent conductive structures. The techniques described herein can improve electrical isolation associated with the described conductive contacts. Other improvements and benefits of the techniques described herein are further discussed below with reference to FIG. 1 through FIG. 28.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

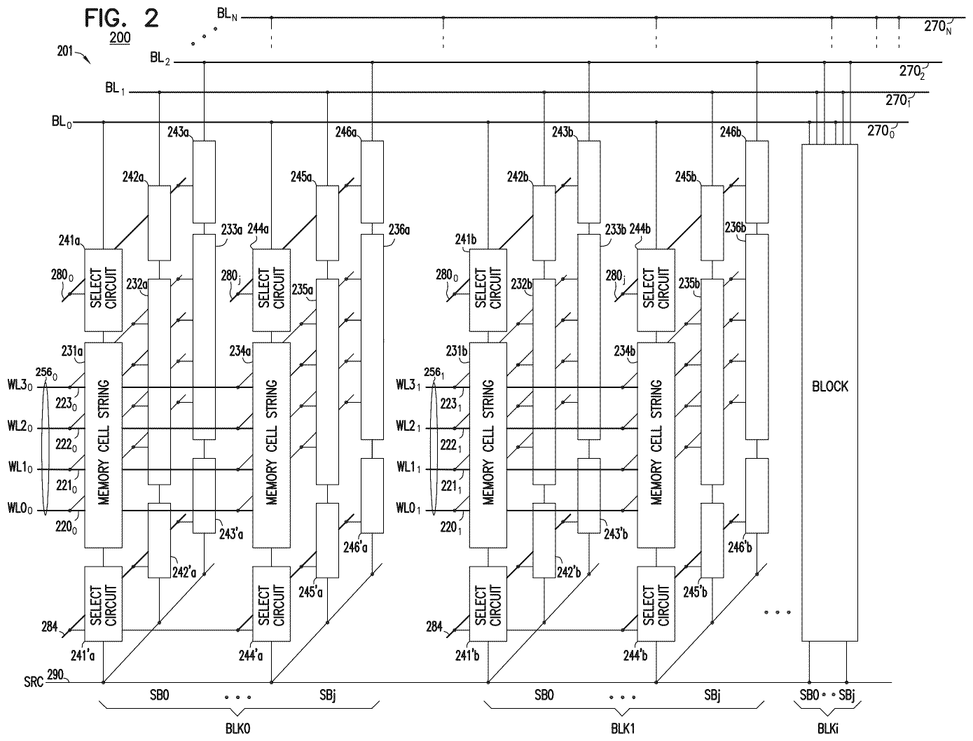

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 24.

FIG. 2 shows a general schematic diagram of a portion of a memory device 200 including a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

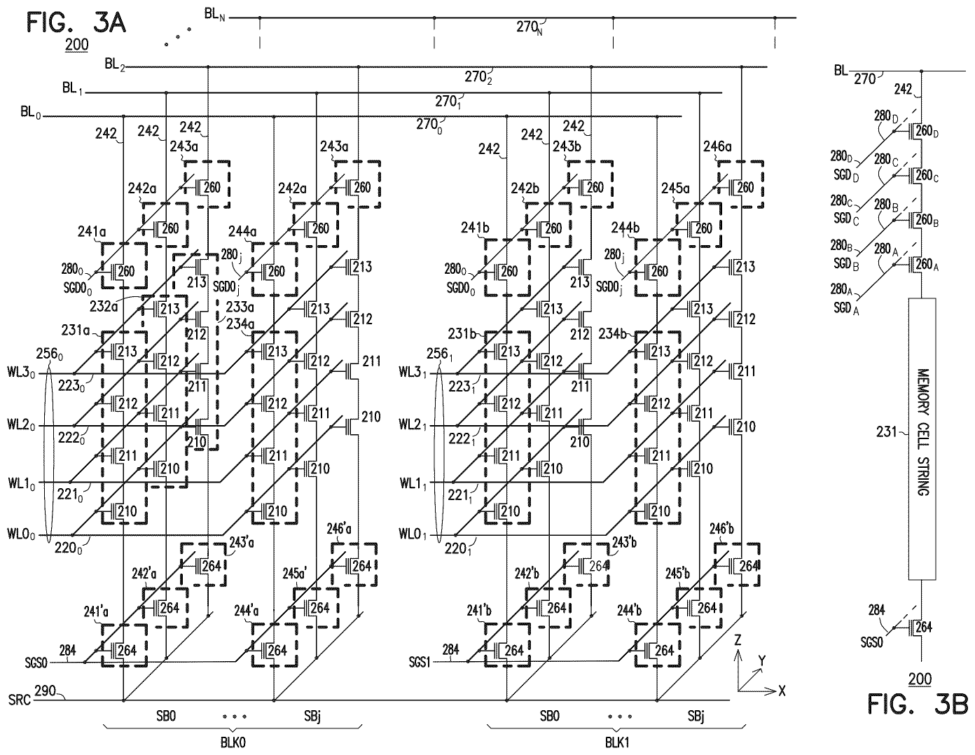

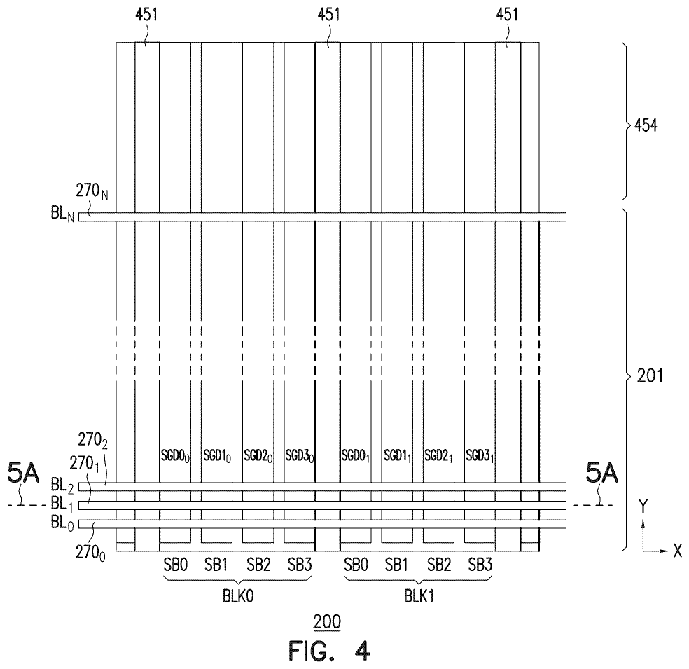

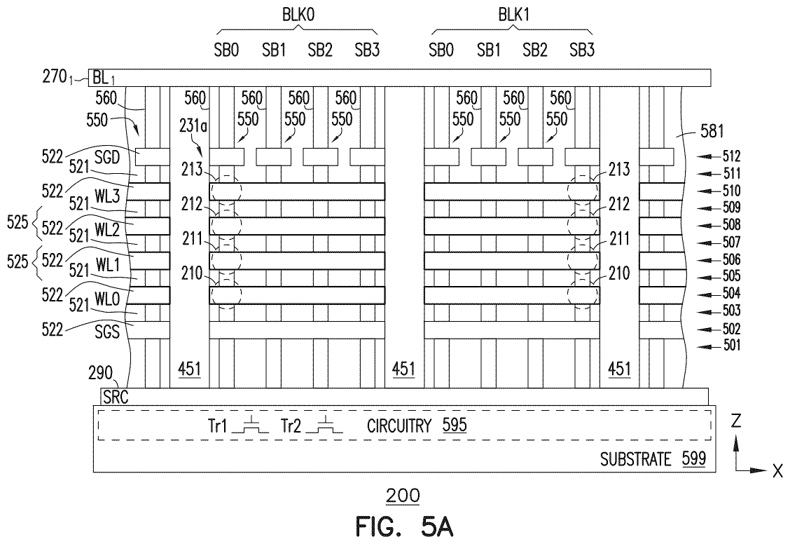

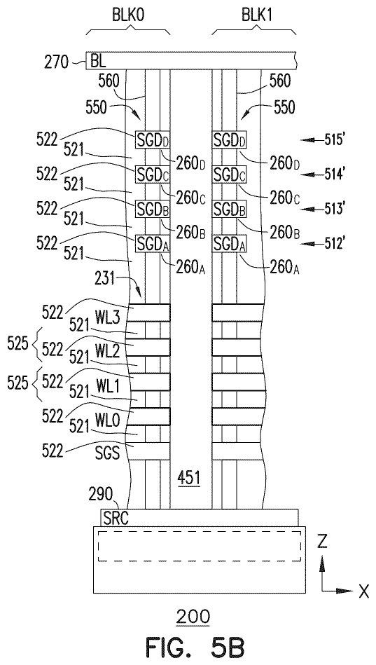

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3A and FIG. 4) and a pillar (e.g., pillar 550 in FIG. 5A) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation).

In this description, a material can include a single material (e.g., a single layer of material) or a combination of multiple materials (e.g., multiple layers of material). For example, a conductive material can include a single conductive material (e.g., a single layer of conductive material) or a combination of multiple conductive materials (e.g., multiple layers of different conductive materials). In another example, a dielectric material can include a single dielectric material (e.g., a single layer of dielectric material) or a combination of multiple dielectric materials (e.g., multiple layers of different dielectric materials).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280o, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280o) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3A) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3A) coupled between source 290 and a respective memory cell string. The source select gate (e.g., transistor) can be controlled (e.g., turned on or turned off) by a signal on a respective source select line based on a voltage provided to the signal.

FIG. 3A shows a detailed schematic diagram including blocks BLK0 and BLK1 of memory device 200 of FIG. 2, according to some embodiments described herein. In FIG. 3A, directions X, Y, and Z in FIG. 3A can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5A). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3A. As shown in FIG. 3A, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3A, similar drain select lines (and their associated signals) are given the same labels for simplicity. However, as shown in FIG. 3A, the drain select lines (from the same block or from different blocks) of memory device 200 are electrically separated from each other and carry different signals (although the signals are given the same labels).

As shown in FIG. 3A, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3A, each of the memory cell strings (e.g., memory cell string 231a) of memory device 200 can include series-connected memory cells that include one of memory cells 210, one of memory cells 211, one of memory cells 212, and one of memory cells 213. FIG. 3A shows an example of four memory cells 210, 211, 212, and 213 in each memory cell string. The number of memory cells in each memory cell string can vary. For example, each memory string can include up to hundreds (or more) of memory cells.

As shown in FIG. 3A, memory device 200 can include conductive connections 242 coupled between respective select gates 260 and respective data lines memory cells to respective data lines 270₀ through 270_{N}. In the physical structure of memory device 200, each conductive connection 242 is part of a contact structure (e.g., contact structure 560 in FIG. 5A) associated with a memory cell pillar (e.g., pillar 550 in FIG. 5A) of memory device 200.

As shown in FIG. 3A, each drain select circuit (e.g., select circuit 241a) can include one of select gates 260. Each source select circuit (e.g., select circuit 241′a) can include one of select gates 264.

Each select gate 260 in FIG. 3A can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor (e.g., FET)) between the portion of the conductive material and the portion of the channel material.

FIG. 3A shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 3B shows an example of memory device 200 including four select gates (e.g., four drain select gates) 260_{A}, 260_{B}, 260_{C}, and 260_{D} associated with four select lines 280_{A}, 280_{B}, 280_{C}, and 280_{D}. Memory device 200 can use signals SGD_{A}, SGD_{B}, SGD_{C}, and SGD_{D} on select lines 280_{A}, 280_{B}, 280_{C}, and 280_{D}, respectively, to control (turn on or turn off) select gates 260_{A}, 260_{B}, 260_{C}, and 260_{D}, respectively. Data line 270 and associated signal BL can be one of data lines 270₀ through 270_{N} associated with one of signals BL₀ through BL_{N}, respectively. Memory cell string 231 and associated conductive connection 242 can be one of the memory cell strings (e.g., memory cell string 231a) associated with conductive connection 242 of memory device 200 of FIG. 3A.

FIG. 3B shows one source select gate (e.g., select gate 264) and one source select signal (e.g., signal SGS0) on a source select line (e.g., select line 284). However, memory device 200 can include two or more source select gates (in the Z-direction) like select gates 260_{A}, 260_{B}, 260_{C}, and 260_{D}.

FIG. 4 shows a top view of a structure of a portion of memory device 200 of FIG. 2 and FIG. 3A including a region of memory array 201 including blocks BLK0 and BLK1, a region 454, and structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3A are also not repeated.

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1). Structures 451 can be called a dielectric structure or a slit structures. The regions of memory device 200 at which structures 451 are located can be called slit regions.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have a structure like block BLK0. As shown in FIG. 4, block BLK1 can include sub-blocks SB0, SB1, SB2, and SB3 and select lines (e.g., drain select lines) SGD0₁, SGD1₁, SGD2₁, and SGD3₁.

A side view (e.g., cross-section) at memory array (memory cell array) 201 of memory device 200 along line 5A-5A in FIG. 4 is shown in FIG. 5A.

FIG. 5A shows a side view (e.g., cross-section) of a structure of a portion of memory device 200 of FIG. 4 including tiers (tiers of materials) 525 that include respective memory cells and control gates associated with (e.g., to control) the memory cells, according to some embodiments described herein. FIG. 5A also partially shows other blocks (on the left and right sides of blocks BLK0 and BLK1) of memory device 200.

As shown in FIG. 5A, memory device 200 can include a substrate 599, source 290 formed over substrate 599, and different levels 501 through 512 over substrate 599 in the Z-direction. Levels 501 through 512 are physical device levels of memory device 200 over substrate 599. Memory device 200 can include a dielectric material 581 formed over at least a portion of memory device 200. Memory cells 210, 211, 212, and 213 of the memory cell strings (e.g., memory cell string 231a in FIG. 3A) of respective sub-blocks SB0, SB1, SB2, and SB3 of each of blocks BLK0 and BLK1 can be formed over substrate 599 and source 290 (e.g., formed vertically in Z-direction in respective levels among levels 501 through 512).

As shown in FIG. 5A, data line 270₁ (associated with signal BL₁) can extend in the X-direction across the blocks (e.g., blocks BLK0 and BLK1 and other blocks) of memory device 200. Data line 270₁ can be shared by respective memory cell strings (including memory cell string 231a) of the blocks.

In FIG. 5A, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5A, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3A. In another example, in block BLK1, the select line indicated by signal SGS can correspond to the select line (e.g., source select line) associated with signals SGS1 of block BLK1 shown in FIG. 3A.

In FIG. 5A, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 3A. In another example, in block BLK1 in FIG. 5A, the control gates indicated by signals WL0, WL1, WL2, and WL3 can correspond to respective control gates associated with signals WL0₁, WL1₁, WL2₁, and WL3₁, respectively, of block BLK1 shown in FIG. 3A.

As shown in FIG. 5A, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form respective control gates (associated with signals WL0, WL1, WL2, and WL3) in the respective block. As shown in FIG. 5A, dielectric materials 521 can be located on respective levels among levels 501 through 512. Conductive materials 522 can be located on respective levels (e.g., levels 502, 504, 506, 508, 510, and 512) among levels 501 through 512 that are interleaved with the levels of dielectric materials 521. Examples of conductive materials 522 (which form the control gates) include a single conductive material (e.g., single metal, e.g., tungsten) or a combination of different layers of conductive materials. For example, each of the control gates of blocks BLK0 and BLK1 can include (e.g., have multi-layers of) aluminum oxide, titanium nitride, tungsten.

As shown in FIG. 5A, dielectric materials 521 can form levels of dielectric materials 521. Conductive materials 522 can form levels of conductive materials 522 that are interleaved with the levels of dielectric materials 521. The levels of dielectric materials 521 and the levels of conductive materials 522 can form tiers 525 of memory device 200. Each tier 525 can include a level of dielectric material 521 and a level of conductive material 522. For simplicity, only some of tiers 525 are labeled in FIG. 5A. As shown in FIG. 5A, tiers 525 can be located one over another and can include respective levels of memory cells 210, 211, 212, and 213, and control gates associated with the memory cells. FIG. 5A shows a few tiers (e.g., only two tiers 525 are labeled) of memory device 200 as an example. However, memory device 200 can include up to hundreds of tiers (or more than hundreds of tiers).

As shown in FIG. 5A, memory device 200 can include pillars (memory cell pillars) 550 in blocks BLK0 and BLK1. Each of pillars 550 can be part of a respective memory cell string (e.g., memory cell string 231a). Each of the pillars 550 can have length extending through at least a portion of the levels of dielectric materials 521 and the levels of conductive materials 522 in the Z-direction (e.g., extending vertically from substrate 599) between substrate 599 and data line 270₁. As shown in FIG. 5A, the Z-direction is also a direction at which the length of pillar 550 extends from one tier to another tier, which is also a direction from levels of dielectric materials 521 to levels of conductive materials 522.

As shown in FIG. 5A, memory device 200 can include contact structures (e.g., data line contact structures) 560. Each pillar 550 can be coupled to a data line by a respective contact structure 560. Each contact structure 560 can be considered as part of a respective pillar 550 and can include a conductive material (or conductive materials) to allow electrical signal between pillar 550 and a respective data line.

As shown in FIG. 5A, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5A, memory device 200 can include circuitry 595 located in (e.g., formed in) substrate 599. At least a portion of the circuitry 595 can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5A, source 290 can include a conductive material (or materials, e.g., different levels of different materials) and can have a length extending in the X-direction. FIG. 5A shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

FIG. 5B shows an example structure of memory device 200 of FIG. 5A including four select gates (e.g., four drain select gates) 260_{A}, 260_{B}, 260_{C}, and 260_{D} associated with a memory cell string (e.g., memory cell string 231). The other elements of memory device 200 of FIG. 5B can be the same as those of memory device 200 shown in FIG. 5A. Memory device 200 of FIG. 5B can represent the structure of memory device 200 that is schematically shown in FIG. 3B. FIG. 5B shows an example of memory device 200 including a multiple of four select gates (e.g., four drain select gates) associated with signals SGD_{A}, SGD_{B}, SGD_{C}, and SGD_{D}. Conductive materials 522 on respective levels 512′, 513′, 514′, and 515′ form the select lines (e.g., four select lines) associated with the select gates. Like memory device 200 of FIG. 5A, memory device 200 of FIG. 5B can include contact structures (e.g., data line contact structures) 560 associated with pillars (memory cell pillars) 550.

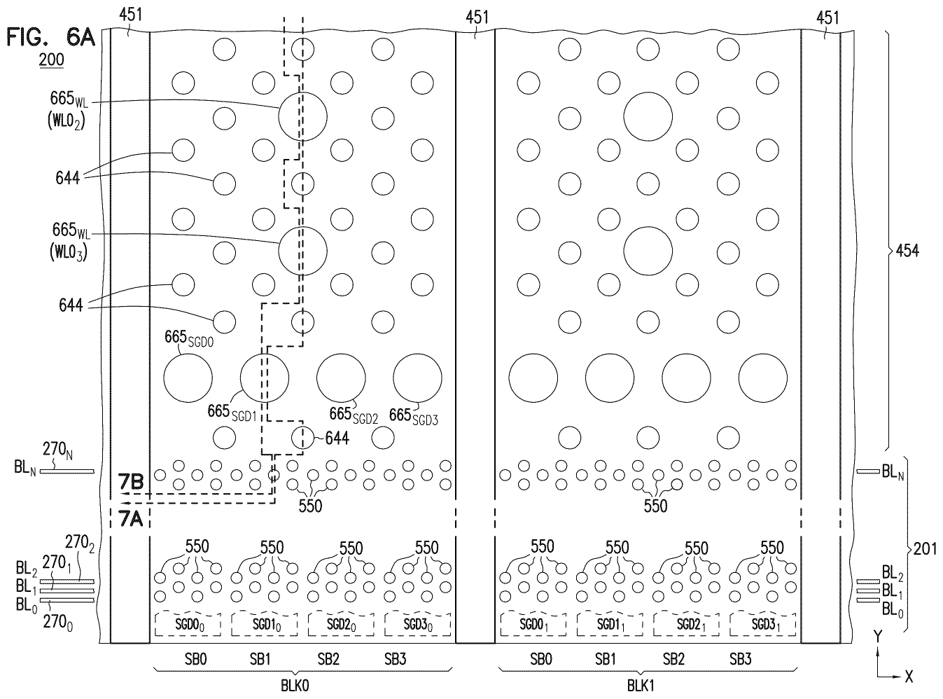

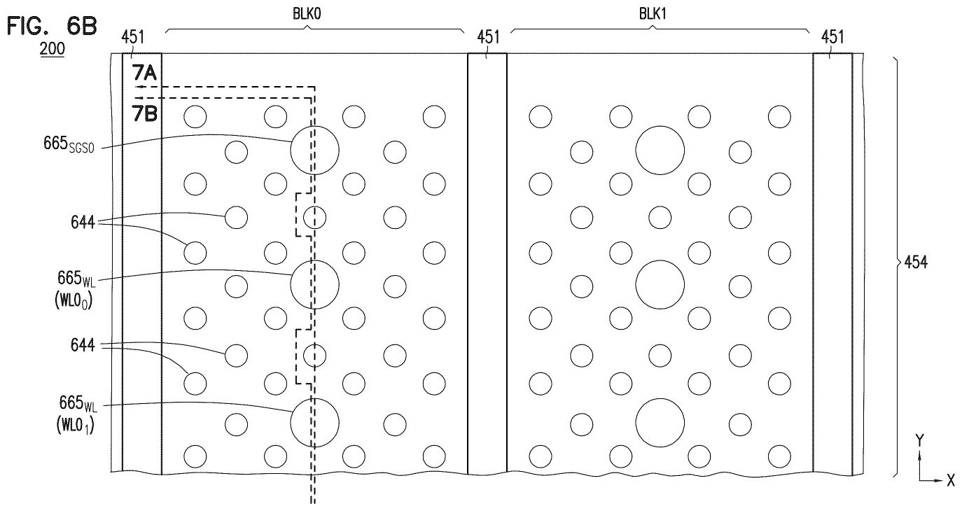

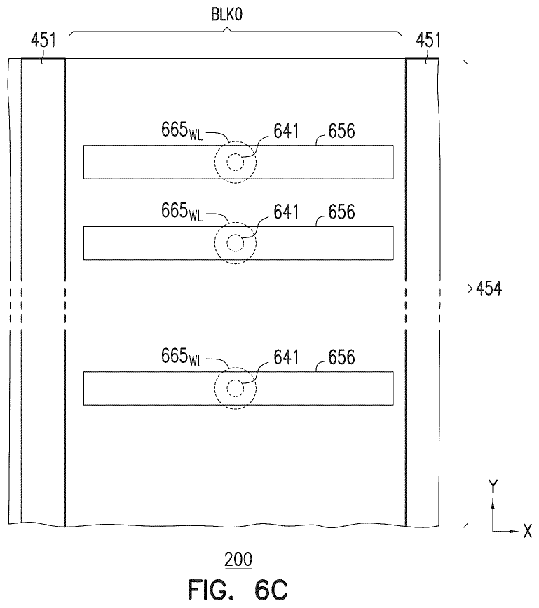

FIG. 6A and FIG. 6B show top views of a structure of memory device 200 of FIG. 4, according to some embodiments described herein. FIG. 6C shows a top view of additional elements of memory device 200 of FIG. 4, according to some embodiments described herein. FIG. 6A shows top views of pillars 550 located in the region included in memory array 201, which is adjacent region 454. As shown in FIG. 6A and FIG. 6B, in region 454, memory device 200 can include conductive contacts (e.g., word line contacts) 665_{WL}, conductive contacts (e.g., drain select line contacts) 665_{SGD0}, 665_{SGD1}, 665_{SGD2}, and 665_{SGD3}), and conductive (e.g., source select line contact) 665_{SGS0} (FIG. 6B) in region 454. Conductive contacts 665_{WL} can include metal (e.g., tungsten or other conductive materials). Although not shown in FIG. 6A and FIG. 6B for simplicity, memory device 200 can include conductive lines 656 (as shown in FIG. 6C) and conductive portions 641 coupled to respective conductive contacts (e.g., conductive contacts 665_{WL}, as shown in FIG. 6C) of memory device 200.

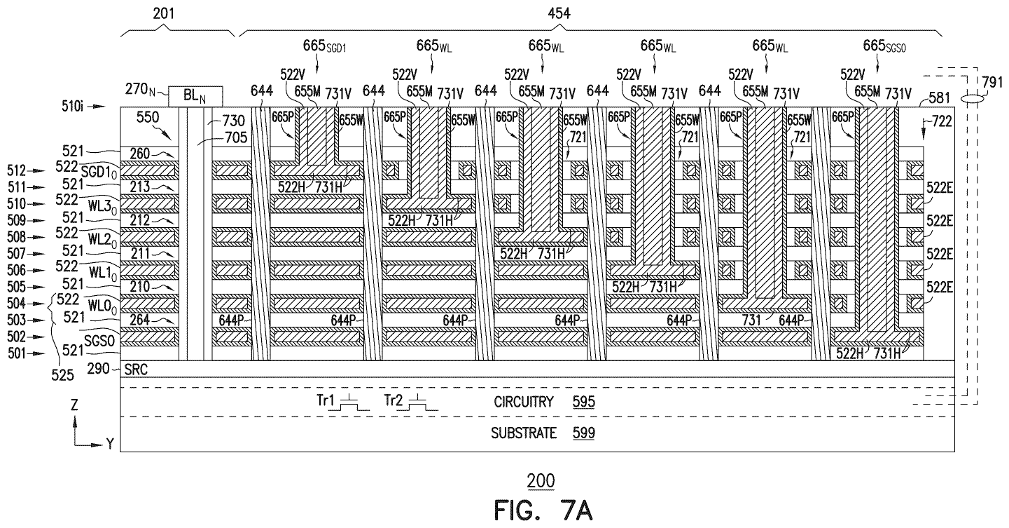

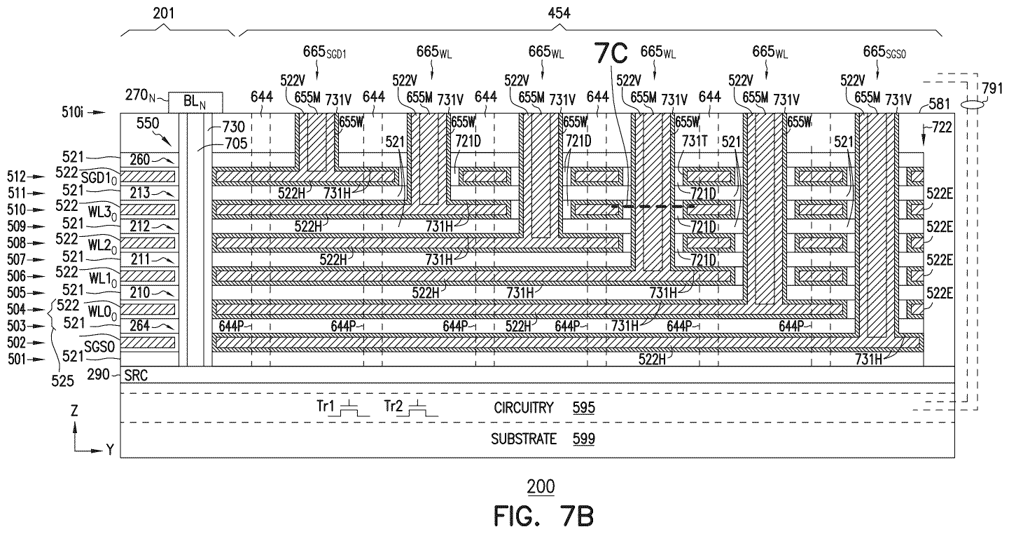

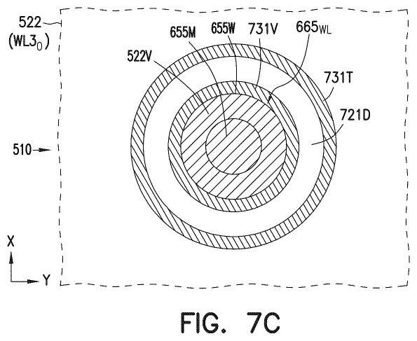

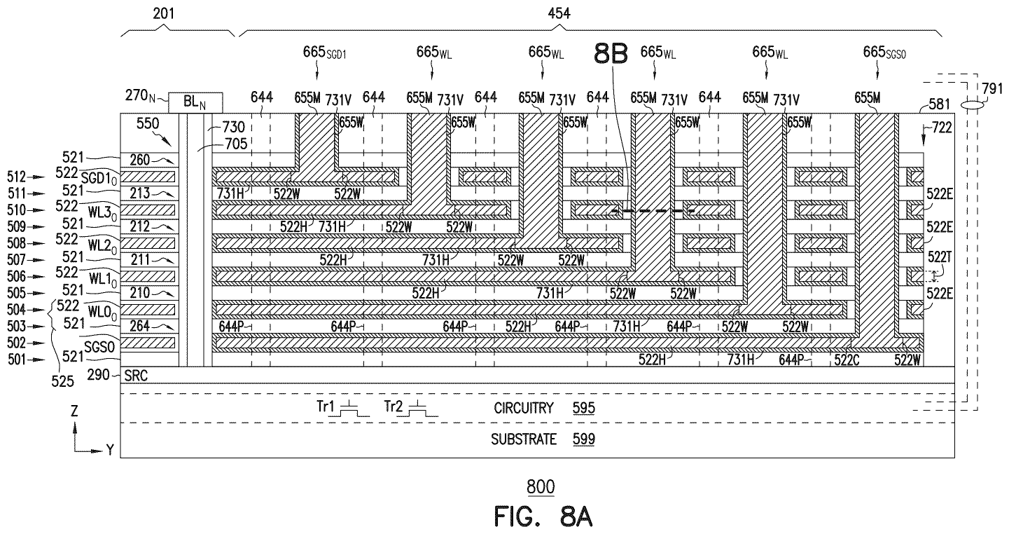

Conductive contacts 665_{WL} can contact (form electrical connection with) respective control gates (located under conductive contacts 665_{WL}, hidden from the top view of FIG. 6A and FIG. 6B). Conductive contacts 665_{WL} can be part of respective access lines (e.g., word lines) of memory device 200. Conductive contacts 665_{WL} allow signals (e.g., signals WL0₀, WL1₀, WL2₀, and WL3₀ in block BLK0 in FIG. 3A) to be provided to respective control gates of block BLK0 through conductive contacts 665_{WL} in FIG. 6A and FIG. 6B. FIG. 7A, FIG. 7B, and FIG. 7C (described in more detail below) show additional views (e.g., cross-sections) of memory device 200, including of details of conductive contacts 665_{WL}.

Similarly, for block BLK1 in FIG. 6A and FIG. 6B, conductive contacts (e.g., not labeled) can be formed at region 454 to allow signals (e.g., signals WL0₁, WL1₁, WL2₁, and WL3₁ in block BLK1 shown in FIG. 3A) to be provided to respective control gates of block BLK1 through the conductive contacts at region 454. Region 454 can be called conductive contact region (e.g., word line conductive contact region) of memory device 200.

FIG. 6A and FIG. 6B also show top views of dielectric structures 644. Each of dielectric structures 644 can include a pillar (e.g., dielectric pillar 644P, shown in FIG. 7A) having a length extending in the Z-direction. Dielectric structures 644 can include a dielectric material (e.g., silicon dioxide).

Dielectric structures 644 can be formed to provide structural support for a portion (e.g., region 454) of memory device 200 (e.g., during part of the processes of forming memory device 200). Dielectric structures 644 can be called support structures at region 454 of memory device 200.

As shown from the top view (e.g., cross-section parallel to the X-Y plane) in FIG. 6A and FIG. 6B, conductive contacts 665_{WL}, 665_{SGD0}, 665_{SGD1}, 665_{SGD2}, and 665_{SGD3}, and 665_{SGS0} can be located side-by-side with respective portions of dielectric structures 644.

In FIG. 6A, select lines associated with signals SGD0₀, SGD1₀, SGD2₀, and SGD3₀ in block BLK0 and signals SGD0₁, SGD1₁, SGD2₁, and SGD3₁ in block BLK1 are partially shown as dotted lines. Each of sub-blocks SB0, SB1, SB2, and SB3 can include multiple rows of pillars 550 associated with a respective select line (one of the select lines associated with signals SGD0₀, SGD1₀, SGD2₀, and SGD3₀). As shown in FIG. 6A, the multiple rows of pillars 550 can be located one after another in the X-direction (having lengths parallel to the Y-direction). FIG. 6A shows an example where each sub-block includes four rows of pillars 550. However, the number of rows in the sub-blocks can be less than four or greater than four.

In FIG. 6A, data lines 270₀ through 270_{N} are partially shown for simplicity. Data lines 270₀ through 270_{N} can extend across (in the X-direction) the blocks (e.g., blocks BL0 and BL1) and can be located over and in electrical contact with pillars 550. Connections (e.g., vertical connections in the Z-direction) between pillars 550 and data lines 270₀ through 270_{N} are not shown in FIG. 6A through FIG. 6C. However, each pillar 550 in the same sub-block of a block can be coupled to a separate (e.g., unique) data line among data lines 270₀ through 270_{N}.

FIG. 6C shows a top view of a portion of memory device 200 including conductive lines 656 associated with block BLK0. For simplicity, only some of conductive lines 656 of memory device 200 are shown in FIG. 6C. Conductive lines 656 can be part of conductive paths (e.g., conductive paths 791 in FIG. 7A) coupled to components (e.g., word line drivers) of circuitry 595 (FIG. 7A) of memory device 200. As shown in FIG. 6C, memory device 200 can include conductive portions 641 that are located under and coupled to respective conductive contacts 665_{WL}. Conductive lines 656 of a block (e.g., BLK0) can be formed (e.g., patterned) such that they can be electrically separated from other conductive lines 656 (not shown) of another block (e.g., block BLK1).

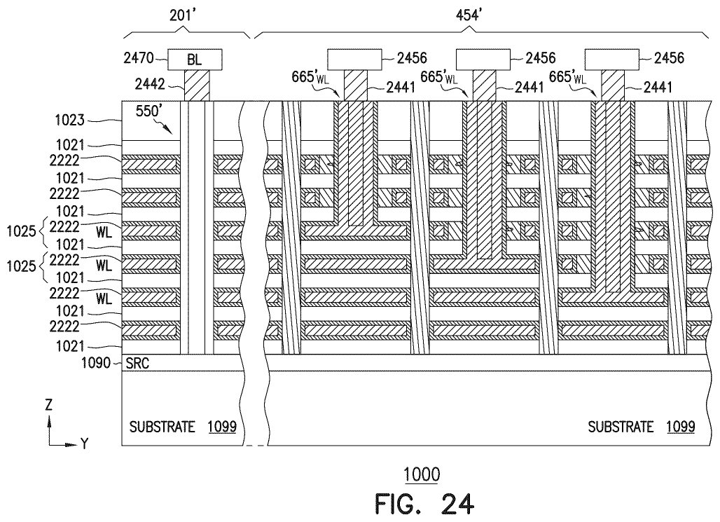

Conductive portions 641 can be similar to (or the same as) conductive portions 2441 (FIG. 24). In FIG. 6C, a conductive portion 641 and a corresponding conductive contact 665 (that are coupled to the same conductive line 656) can be called a conductive contact structure (e.g., a word line contact structure) associated with a respective conductive line 656.

A side view (e.g., cross-section) along line 7A-7A in FIG. 6A and FIG. 6B of block BLK0 are shown in FIG. 7A. A side view (e.g., cross-section) along line 7B-7B in FIG. 6A and FIG. 6B of block BLK0 is shown in FIG. 7B. The view of FIG. 7B is the same as the view of FIG. 7A with the exception of the absence of the cross-sections of dielectric structures 644 in FIG. 7B. FIG. 7C shows a top view (e.g., cross-section) along line 7C of FIG. 7B. The following description refers mainly to FIG. 7A. However, the same description is also applicable to FIG. 7B, which shows the same elements of memory device 200 as FIG. 7A.

FIG. 7A shows a side view of a portion of memory device 200 including conductive contacts 665_{WL}, 665_{SGD1}, and 665_{SGS0} in region 454, and pillar 550 in memory array 201, according to some embodiments described herein. Levels 501 through 512 and tiers 525 of memory device 200 in FIG. 7A are the same as those shown in FIG. 5A. As shown in FIG. 7A, pillar 550 can be located in the portion of memory device 200 that includes memory array 201, which is also shown in top view in FIG. 4 and FIG. 6A and FIG. 6B. Pillar 550 can extend through conductive materials 522 (which form the control gates and the select lines) and dielectric materials 521 in the portions that include memory array 201.

As shown in FIG. 7A, memory device 200 can include a structure 730 and a dielectric material 705 that can be part of pillar 550. Structure 730 and a dielectric material 705 can extend continuously (in the Z-direction) along the length of the respective pillar 550. Dielectric material 705 can include silicon dioxide. Structure 730 can be electrically coupled to source 290 and a respective data line (e.g., one of data line 270₀ through 270_{N} in FIG. 3A and FIG. 6A). Structure 730 of a respective pillar 550 in a block is adjacent portions of respective control gates of that block. For example, structure 730 of pillar 550 in block BLK0 is adjacent the control gates associated with signals WL0₀, WL1₀, WL2₀, and WL3₀, respectively.

Structure 730 can include a conductive structure that can be part of a conductive path (e.g., pillar channel structure) to conduct current between a respective data line (e.g., one of data lines 270₀ through 270_{N} in FIG. 3A and FIG. 6A) coupled to structure 730 and source 290. Structure 730 can also include a material (or materials) that can form a charge storage element (e.g., a memory element) of a respective memory cell (among memory cells 210, 211, 212, and 213) located along a portion of pillar 550. As an example, structure 730 can be part of an ONOS (SiO₂, Si₃N₄, SiO₂, Si) where Si₃N₄ material can form a charge storage element of a respective memory cell, and Si material can be part of the pillar channel structure of pillar 550. In another example, structure 730 include can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure) where the floating gate structure can form a charge storage element of a respective memory (among memory cells 210, 211, 212, and 213) located along a portion of pillar 550.

As shown in FIG. 7A, dielectric structures 644 can include respective pillars (dielectric pillars) 644P that can include respective lengths extending in the Z-direction. Dielectric structures 644 can have the same length (e.g., the length from level 510i to the level of source 290). Pillars (dielectric pillars) 644P can be called support pillars in region 454 of memory device 200.

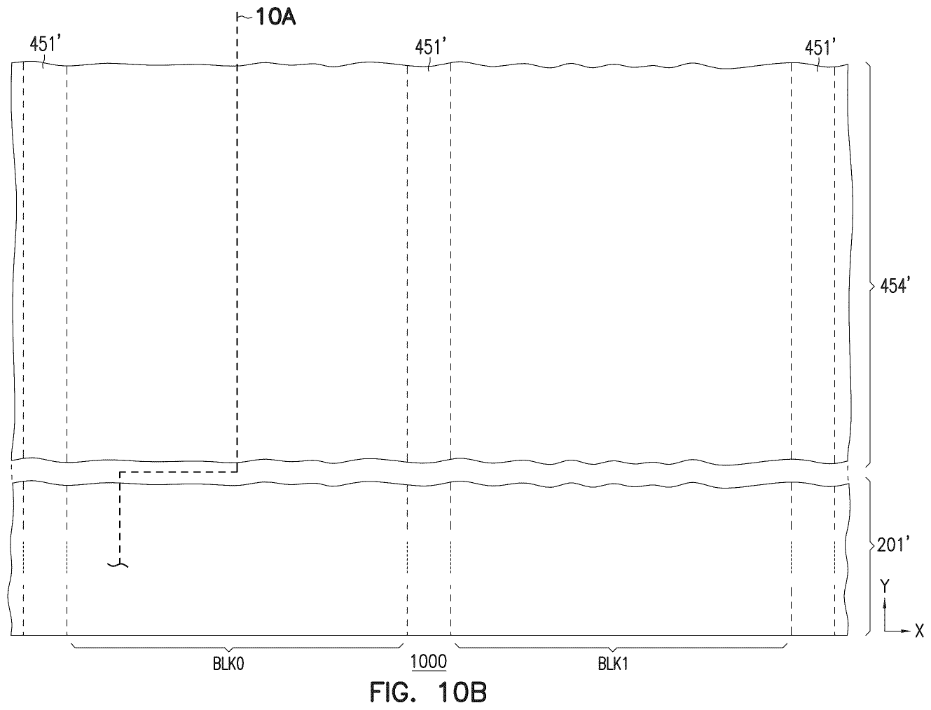

During the processes of forming memory device 200 that can be similar to the processes of forming memory device 1000 of FIG. 10A through FIG. 24, collapse (e.g., in the Z-direction) of some structures (e.g., collapse in part of the levels of conductive materials 522 in region 454) of memory device 200 may occur. Dielectric structure 644 can be formed in memory device 200 to prevent such collapse.

As shown in FIG. 7A, dielectric structures 644 can extend through (e.g., go through) and contact respective portion of dielectric materials 521 and conductive materials 522. Dielectric structures 644 can contact (e.g., land on) source 290. Dielectric structures 644 are electrically separated from conductive materials 522. Each of dielectric structures 644 can contact dielectric materials 521 and conductive materials 522. Dielectric structures 644 are electrically separated from conductive materials 522. As shown in FIG. 7A, dielectric structure 644 can be between (in the Y-direction in FIG. 7A) pillar (memory cell pillar) 550 and edges 522E of respective levels of conductive materials 522.

As shown in FIG. 7A, memory device 200 can include conductive paths (e.g., conductive routings) 791 to form circuit paths between circuitry 595 and other elements of memory device 200. For example, conductive lines 656 (FIG. 6C) associated with the control gates (e.g., control gates associated with signals WL0₀, WL1₀, WL2₀, and WL3₀ in FIG. 7A) of memory device 200 can be part of (or can be coupled to) conductive paths 791. This allows the control gates to couple to circuitry 595 through conductive lines 656 (FIG. 6C) and conductive paths 791 (FIG. 7A).

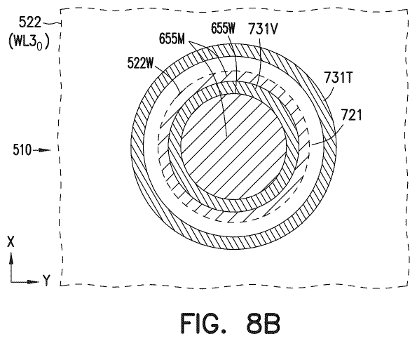

As shown in FIG. 7A and FIG. 7B, each conductive material 522 can include a conductive portion (e.g., horizonal conductive portion) 522H and a conductive portion (e.g., vertical conductive portion) 522V joining (directly coupled to) conductive portion 522H. Conductive portion 522H can extend (e.g., extend horizontally) in the Y-direction. Conductive portion 522V can extend (e.g., extend vertically) in the Z-direction. For simplicity, FIG. 7A shows conductive portion 522H and 522V joint each other and form an angle of 90 degrees at a respective contact (e.g., conductive contact 665_{WL}). However, at a respective conductive contact (e.g., conductive contact 665_{WL}) the angle between conductive portion 522H and conductive portion 522V can be different from 90 degrees. For example, the angle between a conductive portion 522H and a respective conductive portion 522V can be in a range of angles (e.g., a range from 80 degrees to 100 degrees) depending on which side (e.g., left or right in the Y-direction) of a respective conductive contact that conductive portion 522V is located. In an alternative structure (e.g., shown in FIG. 8A, described below) of memory device 200, conductive portions 522V can be omitted from (not included in) the memory device (e.g., memory device 800 in FIG. 8A).

In FIG. 7A, conductive portions 522H can form part of respective control gates (e.g., the control gate associated with signals WL0₀, WL1₀, WL2₀, and WL3₀) of memory device 200. For example, conductive portion 522H of conductive material 522 on level 506 can form part the control gate associated with signal WL1₀. In another example, conductive portion 522H of conductive material 522 on level 508 can form part the control gate associated with signal WL2₀.

As shown in FIG. 7A and FIG. 7B, edges 522E of conductive materials 522 are part of respective conductive portions 522H. Conductive portions 522H can have the same length in the Y-direction measuring between pillar 550 and edges 522E of respective the control gates, such that edges 522E can be aligned (e.g., vertically aligned) with each other at a reference location (e.g., reference point) 722 in the Y-direction.

As shown in FIG. 7A, the control gates associated with signals WL0₀, WL1₀, WL2₀, and WL3₀, and the select lines associated with signals (e.g., drain select signal and source select signal) SGD0₀ and SGS0 can be structured (e.g., patterned), such that they may have the same length in the Y-direction. For example, the control gates (formed from respective conductive portions 522H of conductive materials 522) associated with signals WL0₀, WL1₀, WL2₀, and WL3₀ can have the same length (in the Y-direction) measuring between pillar 550 and edges 522E of respective the control gates.

As shown in FIG. 7A, the conductive contacts (e.g., conductive contact 665_{WL}, 665_{SGD1}, and 665_{SGS0}) of memory device 200 can be between pillar 550 and edges 522E. For example, the conductive contact 665_{WL} (which can be part of conductive pillar 665P) associated with the control gate associated with signal WL1₀ on level 506 is between pillar 550 and edge 522E of conductive material 522 on level 506 and also between pillar 550 and edge 522E of conductive material 522 on level 508 (associated with signal WL2₀). In another example, the conductive contact 665_{WL} (which is part of conductive pillar 665P) associated with the control gate associated with signal WL2₀ on level 508 is between pillar 550 and edge 522E of conductive material 522 on level 508 and also between pillar 550 and edge 522E of conductive material 522 on level 506 (associated with signal WL1₀).

As shown in FIG. 7A, conductive contacts (e.g., word line contacts) 665_{WL}, conductive contact (e.g., drain select line contact) 665_{SGD1}, and conductive contact (e.g., source select line contact) 665_{SGS0} can include respective pillars (conductive pillars) 665P. Pillars 665P can include different (unequal) lengths extending in the Z-direction. The length of a particular conductive contact 665_{WL} (which is also the length of its associated pillar 665P) can be a distance (the measurement) in the Z-direction from the control gate associated with that particular conductive contact to a reference location (e.g., at level 510i) in memory device 200. For purposes of measuring the lengths of different conductive contacts (e.g., conductive contact 665_{WL}) in this description, the same reference location (e.g., at level 510i) with respect to the Z-direction is used for the length measurement.

For example, as shown in FIG. 7A, level 510 is the level of the conductive material 522 that forms the control gate associated with signal WL3₀. Thus, the length of the conductive contact 665_{WL} coupled to the control gate associated with signal WL3₀ can be the distance (the measurement) in the Z-direction from level 510i to level 510 (e.g., to the top of conductive portion 522H on level 510). In another example, as shown in FIG. 7A, level 508 is the level of the conductive material 522 that forms the control gate associated with signal WL2₀. Thus, the length of the conductive contact 665_{WL} coupled to the control gate associated with signal WL2₀ can be the distance (the measurement) in the Z-direction from level 510i to level 508 (e.g., to the top of conductive portion 522H on level 508).

As shown in FIG. 7A, each conductive contact 665_{WL} can include a conductive material 665M (that forms part of pillar 665P) that extends through (e.g., goes through) respective portions of dielectric materials 521 and conductive materials 522. Conductive material 655M can have the same conductive material (e.g., tungsten) as conductive materials 522. Alternatively, conductive material 655M can have a conductive material that is different from conductive materials 522.

In FIG. 7A, each conductive portion 522V adjacent conductive material 665M of a respective conductive contact can be considered as part of (can be included in) the respective conductive contact. For example, conductive portion 522V of conductive material 522 on level 506 can be part of conductive contact 665_{WL} associated with (coupled to) conductive material 522 on level 506. In another example, conductive portion 522V of conductive material 522 on level 508 can be part of conductive contact 665_{WL} associated with (coupled to) conductive material 522 on level 508.

As shown in FIG. 7A, each conductive contact 665_{WL} can include a side wall (e.g., a vertical side wall) 665W in the Z-direction. Conductive portion 522V can be part of side wall 665W. Conductive material 665M (that forms part of pillar 665P) can also be part of side wall 665W when conductive portion 522V is omitted from (not included in) the conductive contacts (e.g., conductive contacts 665_{WL}) of the memory device (like memory device 800 of FIG. 8A).

As shown in FIG. 7A and FIG. 7B, memory device 200 can include dielectric portions (e.g., horizontal dielectric portions) 731H and dielectric portions (e.g., vertical dielectric portions) 731V. Memory device 200 can also include dielectric portions (e.g., in-tier dielectric portions) 731T (labeled in FIG. 7B and FIG. 7C) located in respective tiers (associated with levels 502, 504, 506, 508, 510, and 512). Dielectric portions 731H, 731V, and 731T can form a dielectric liner structure. As shown in FIG. 7A and FIG. 7B, dielectric portions 731H, 731V, and 731T (labeled in FIG. 7B) can form relatively thin layers of dielectric material. Thus, dielectric portions 731H, 731V, and 731T can be called dielectric liners.

Dielectric portions 731H, 731V, and 731T are formed from a dielectric material (or dielectric materials). Dielectric portions 731H, 731V, and 731T can form a dielectric liner structure. Dielectric portions 731H, 731V, and 731T can be formed concurrently (e.g., formed simultaneously in the same process step). Thus, dielectric portions 731H, 731V, and 731T can have the same dielectric material.

An example of a dielectric material for dielectric portions 731H and 731V includes a high-k dielectric material. Examples of high-k dielectric materials include hafnium oxide (e.g., HfO₂), aluminum oxide (e.g., Al₂O₃), and other high-k dielectric materials. A high-k dielectric material is a dielectric material having a dielectric constant greater than the dielectric constant of silicon dioxide. Alternatively, dielectric portions 731V (or dielectric portions 731H, 731V, and 731T) can be formed from a dielectric material (e.g., silicon dioxide) having a dielectric constant less than a dielectric constant of a high-k dielectric material. However, in memory device 200, using a high-k dielectric material (e.g., instead of silicon dioxide) for dielectric portions 731V (or dielectric portions 731H, 731V, and 731T) can improve isolation of conductive structures (e.g., conductive contacts 665_{WL} and the control gates) adjacent dielectric portions 731V. This improved isolation can lead to improved operations (e.g., read or write operations) of memory device 200.

As shown in FIG. 7A and FIG. 7B, a conductive portion 522H on a respective tier (e.g., one of levels 502, 504, 506, 508, 510, and 512) can be between (e.g., sandwiched between) two portions 731H of in the respective tier. For example, conductive portion 522H on level 506 can be between (e.g., sandwiched between) two portions 731H on level 506.

For simplicity, FIG. 7A shows dielectric portion 731H and 731V joint each other and form an angle of 90 degrees at a respective contact (e.g., conductive contact 665_{WL}). However, at a respective conductive contact (e.g., conductive contact 665_{WL}) the angle between dielectric portion 731H and dielectric portion 731V can be different from 90 degrees. For example, the angle between a dielectric portion 731H and a respective dielectric portion 731V can be in a range of angles (e.g., a range from 80 degrees to 100 degrees) depending on which side (e.g., left or right in the Y-direction) of a respective conductive contact that dielectric portion 731V is located.

As shown in FIG. 7A, memory device 200 can include dielectric structures 721 at respective conductive contacts 665_{WL}, 665_{SGD1}, and 665_{SGS0}. Dielectric structures 721 can include dielectric material (dielectric portions) 721D (labeled in FIG. 7B) located on respective levels 502, 504, 506, 508, 510, and 512, which are the same as the levels where conductive portions 522H are located. Dielectric materials 721D of dielectric structures 721 can include silicon dioxide for example. Dielectric materials 721D can have the same dielectric material (e.g., silicon dioxide) as dielectric materials 521 on respective adjacent levels 501, 503, 505, 507, 509, and 511. As shown in FIG. 7A and FIG. 7B, a dielectric portion 731V can be between a respective conductive contact (e.g., conductive contact 665_{WL}) and dielectric materials 721D of dielectric structure 721.

At a respective conductive contact (e.g., at one of conductive contacts 665_{WL}, 665_{SGD1}, and 665_{SGS0}), dielectric portion 731V (which can include a high-k dielectric material) and a respective dielectric structure 721 (which can include silicon dioxide) can form multiple dielectric liners of an isolation structure. The multiple dielectric liners include the dielectric material of dielectric portion 731V and the dielectric material (e.g., dielectric materials 721D) of dielectric structure 721. The isolation structure can isolate (electrically isolate) a respective conductive contact from conductive materials 522 (e.g., from conductive portions 522H) except for one of the conductive materials 522 (e.g., one of conductive portions 522H) that forms the control gate associated with the respective conductive contact. For example, as shown in FIG. 7B, at conductive contact 665_{WL} coupled to conductive portion 522H on level 506, dielectric portion 731V and the adjacent dielectric structure 721 can isolate conductive contact 665_{WL} (coupled to conductive portion 522H on level 506) from conductive portions 522H on levels 508, 510, and 512, except for conductive portion 522H on level 506.

FIG. 7C shows a top view (e.g., cross-section) along line 7C in FIG. 7B. As shown in FIG. 7B and FIG. 7C, dielectric portion (e.g., dielectric liner) 731V can be adjacent (e.g., contacting side wall 665W) and surrounding the conductive material (e.g., conductive portion 522V and conductive material 665M) of conductive contact 665_{WL}. Dielectric material 721D can be adjacent (e.g., contacting) and surrounding dielectric portion 731V. Dielectric portion (e.g., dielectric liner) 731T can be adjacent (e.g., contacting) and surrounding dielectric material 721D. As shown in FIG. 7B, dielectric portion (e.g., dielectric liner) 731T can also be between a respective conductive portion 522H and a respective dielectric material 721D.

As shown in FIG. 7B and FIG. 7C, dielectric material (e.g., silicon dioxide) 721D is between conductive portion 522H (of conductive material 522 on level 510) and side wall 655W of conductive contact 665_{WL}. The dielectric material (e.g., high-k dielectric material) of dielectric portion 731V is between dielectric material 721D and side wall 655W of conductive contact 665_{WL}.

FIG. 8A shows a memory device 800 that can be a variation of memory device 200, according to some embodiments described herein. FIG. 8B shows a top view (e.g., cross-section) along line 8B of FIG. 8A. Memory device 800 can include elements that are similar to or the same as the elements of memory device 200 of FIG. 7A and FIG. 7B. For simplicity, descriptions of similar or the same elements between memory devices 200 and 800 are not repeated. In comparison with memory device 200 of FIG. 7A, memory device 800 of FIG. 8A omits (does not include) conductive portions 522V. Thus, as shown in FIG. 8A and FIG. 8B, conductive material 665M can be part of side wall 665W and can be adjacent (e.g., can contact) dielectric portion (e.g., dielectric liner) 731V.

As shown in FIG. 8A, each level of conductive materials (each conducive level) 522 can include a thickness 522T (in the Z-direction) and a side wall 522W. For simplicity, only one thickness 522T is labeled in FIG. 8A. The height of side wall 522W and thickness 522T can have the same dimension (e.g., measured in meter unit). As shown in FIG. 8A and FIG. 8B, conductive material 665M of conductive contact 665_{WL} can be adjacent (e.g., can contact) side wall 522W of a respective conductive material 522. Memory device 800 can include improvements and benefits similar to memory device 200 described above.

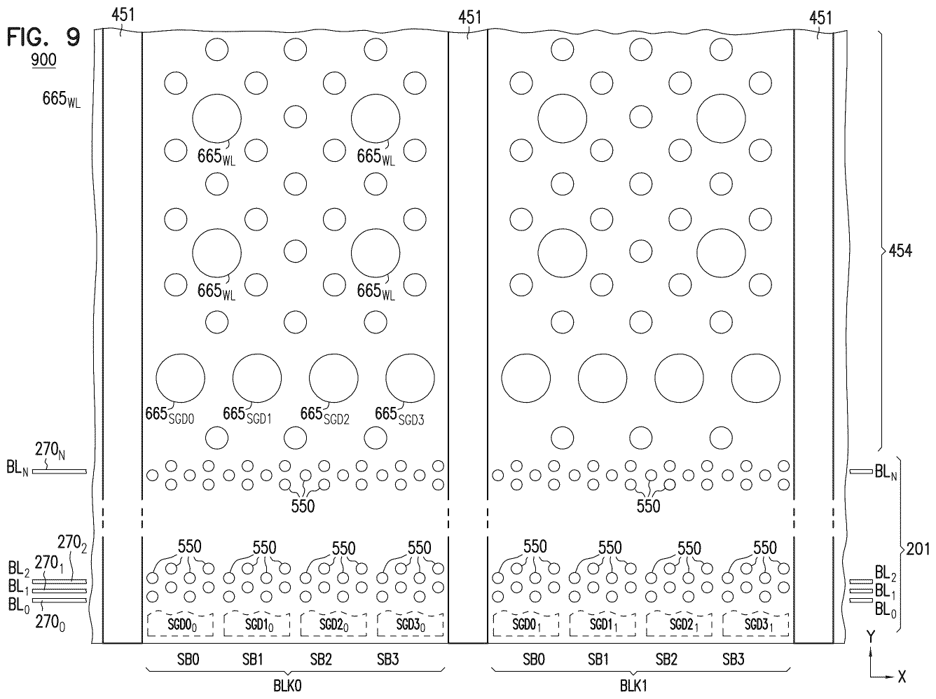

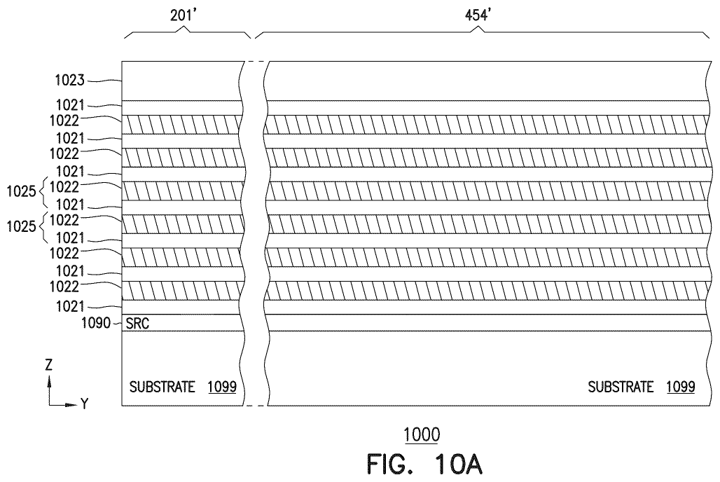

FIG. 9 shows a memory device 900 that can be a variation of memory device 200, according to some embodiments described herein. As shown in FIG. 9A, memory device 900 can include elements that are similar to or the same as the elements of memory device 200 of FIG. 6A. For simplicity, descriptions of similar or the same elements between memory devices 200 and 900 are not repeated. In comparison with memory device 200 (FIG. 6A), memory device 900 (FIG. 9) can include a higher number of conductive contacts (e.g., conductive contacts 665_{WL}) in region 454. For example, as shown in FIG. 9, memory device 900 can include multiple (e.g., two are shown as an example) conductive contacts 665_{WL} in region 454 that may be formed (e.g., formed in respective rows) in the X-direction. In the example of FIG. 9, multiple conductive contacts 665_{WL} (e.g., conductive contacts in the same row in the X-direction) can be coupled to (can contact) the same control gate. Alternatively, multiple conductive contacts (e.g., conductive contacts in the same row in the X-direction) can be coupled to (can contact) different control gates. Memory device 900 can include improvements and benefits similar to memory device 200 described above.

The above description with reference to FIG. 2 through FIG. 9 describes the structure of memory devices 200, 800, and 900. Some or all of the structure of memory devices 200, 800, and 900 can be formed using processes associated with the processes described below with reference to FIG. 10A through FIG. 28.

FIG. 10A through FIG. 24 show different views of elements during processes of forming a memory device 1000, according to some embodiments described herein. FIG. 10A shows a side view (e.g., cross-section) in the Y-direction of a portion of memory device 1000. FIG. 10B shows the locations of the side view of memory device 1000 of FIG. 10A that is taken along line 10A of FIG. 10B. Line 10A in FIG. 10B is similar to part of line 7A of FIG. 6A and FIG. 6B.

In FIG. 10B, the region included in memory array 201′ is similar to the region included in memory array 201 of memory device 200 in FIG. 6A. Region 454′ in FIG. 10B is similar to region 454 of memory device 200 in FIG. 6A. In FIG. 10B, regions (e.g., slit regions) 451′ can be similar to the regions of structures 451 (FIG. 4) of memory device 200.

In FIG. 10A, the process of forming memory device 1000 can include forming a material 1090 over substrate 1099. Material 1090 can form part of a source (e.g., associated with signal SRC) that is similar to source 290 of FIG. 7A. Substrate 1099 is similar to (e.g., can correspond to) substrate 599 (FIG. 7A) of memory device 200.

The processes associated with FIG. 10A include forming dielectric materials (levels of dielectric materials) 1021 and dielectric materials (levels of dielectric materials) 1022 over substrate 1099 (e.g., over material 1090 associated with signal SRC). Dielectric materials 1021 can include silicon dioxide. Dielectric materials 1022 can include silicon nitride. Dielectric materials 1021 and 1022 can be sequentially formed one material after another over substrate 1099 in an interleaved fashion, such that dielectric materials 1021 can be interleaved with dielectric materials 1022. A dielectric material 1023 may also be formed over the interleaved dielectric materials 1021 and 1022.

As shown in FIG. 10A, dielectric materials 1021 and 1022 can form tiers (tiers of materials) 1025. Tiers 1025 are located one over another in the Z-direction. Each tier 1025 can include a respective level of dielectric material 1021 and a respective level of dielectric material 1022.

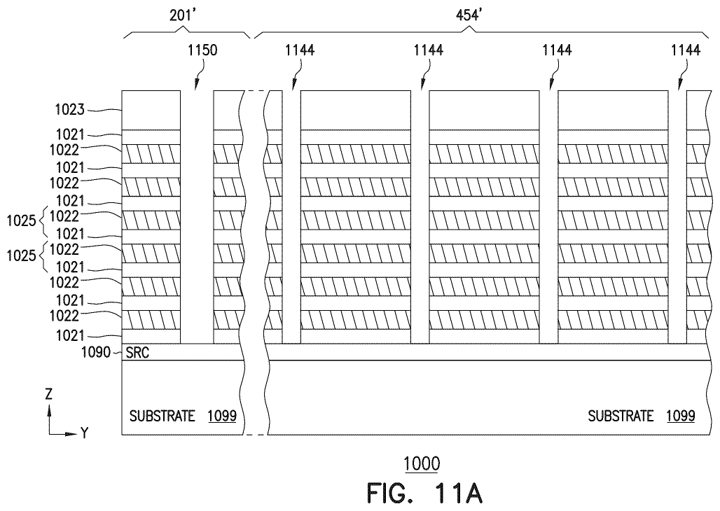

FIG. 11A and FIG. 11B show memory device 1000 after openings (e.g., holes) 1150 and 1144 are formed. Forming openings 1150 and 1144 can include removing (e.g., etching) a portion of dielectric material 1023 and dielectric materials 1021 and 1022 at the locations of contact openings 1150 and 1144.

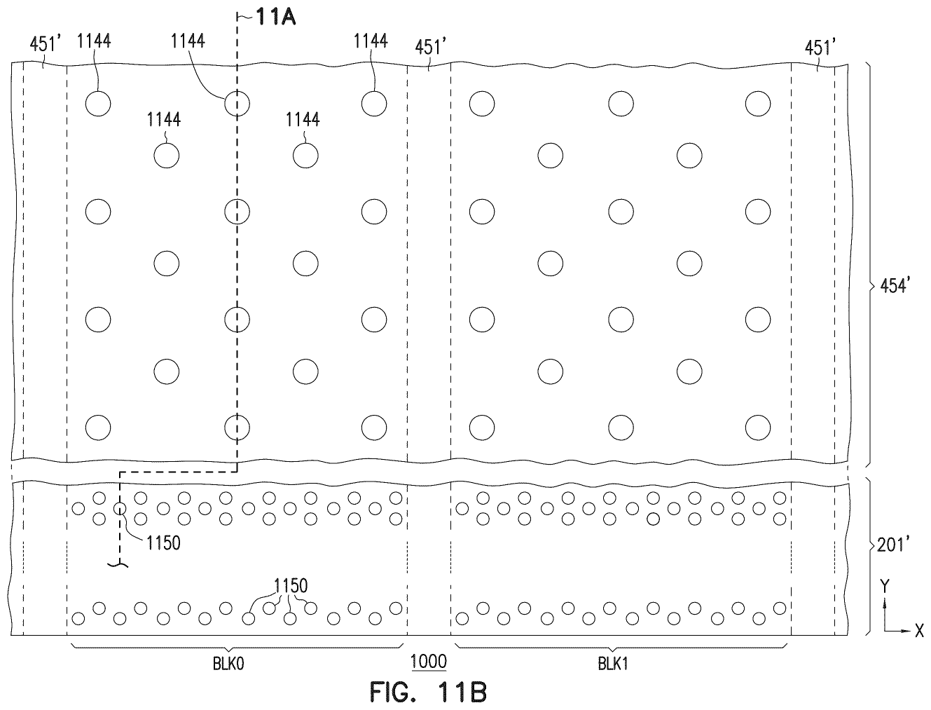

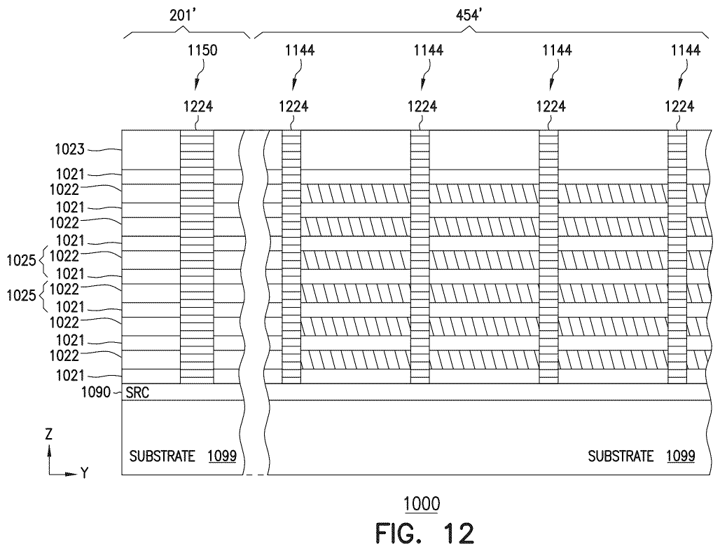

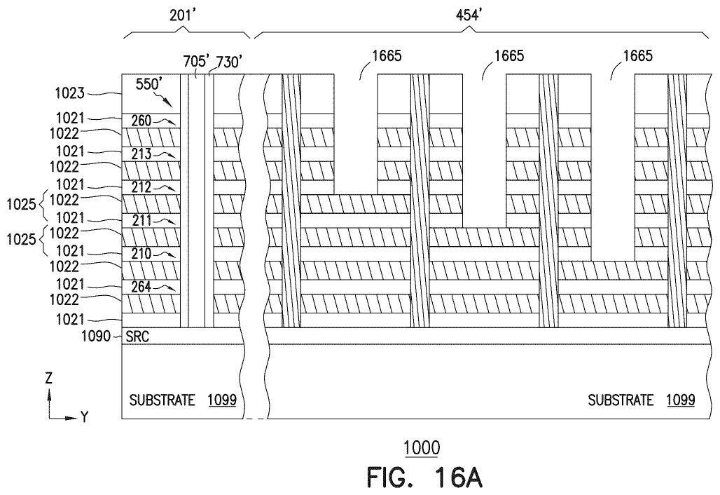

For simplicity, a top view (e.g., like FIG. 10B and FIG. 11B) of memory device 1000 are omitted from FIG. 12 through FIG. 24 (except FIG. 16B) associated with subsequent processes of forming a memory device 200.

FIG. 12 shows memory device 1000 after a material (or materials) 1224 is formed (e.g., filled) in openings 1150 and 1144. In subsequent processes of forming memory device 1000, material 1224 can be removed (e.g., at different times) from openings 1150 and 1144. Thus, material 1224 can be called a sacrificial material. An example of material 1224 can include carbon or other materials. Forming material 1224 can include forming a material (e.g., carbon) in openings 1150 and 1144. A chemical mechanical polishing (CMP) process can be performed after material 1224 is formed.

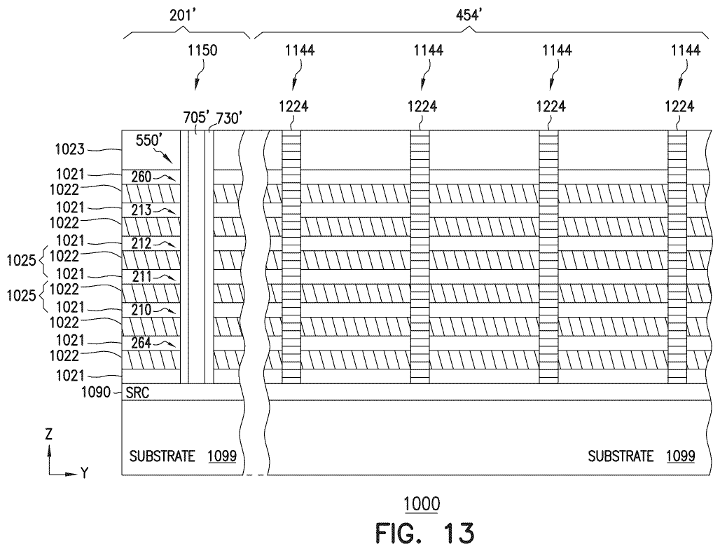

FIG. 13 shows memory device 1000 after pillars (memory cell pillars) 550′ including structure 730′ and a dielectric material 705′ are formed. Pillars 550′, structure 730′, and dielectric material 705′ are similar to (e.g., can correspond to) pillars 550, structure 730, and dielectric material 705 of memory device 200 of FIG. 7A. Forming pillars 550′ can include removing (exhuming) material 1224 from openings 1150 in the region of memory cell array 201′, and forming pillars 550′ (which include structure 730′ and dielectric material 705′) in the locations of openings 1150 (labeled in FIG. 11A and FIG. 11B). Material 1224 in openings 1144 (in region 454′) can remain (not be removed) during the processes associated with FIG. 13. Similar to pillar 550 (FIG. 7A), each pillar 550′ of FIG. 13 can include select gates 260 and 264 and memory cells (e.g., like memory cells 210, 211 212, and 213 in FIG. 7A) of a respective memory cell string.

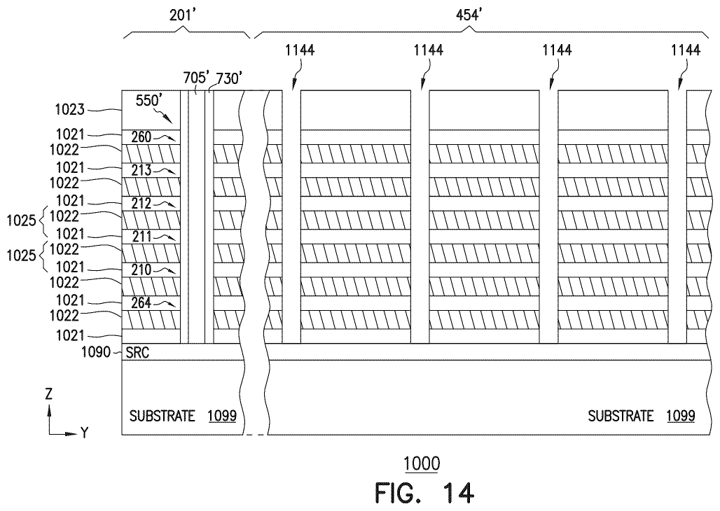

FIG. 14 shows memory device 1000 after material 1224 (labeled in FIG. 12) is removed (e.g., exhumed) from openings 1144.

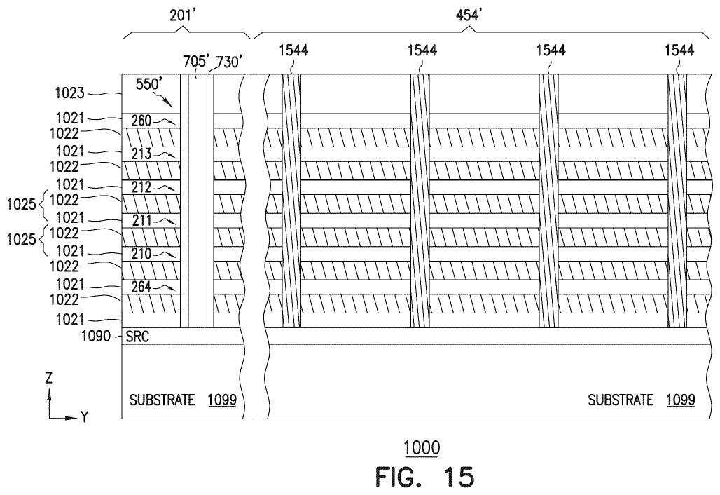

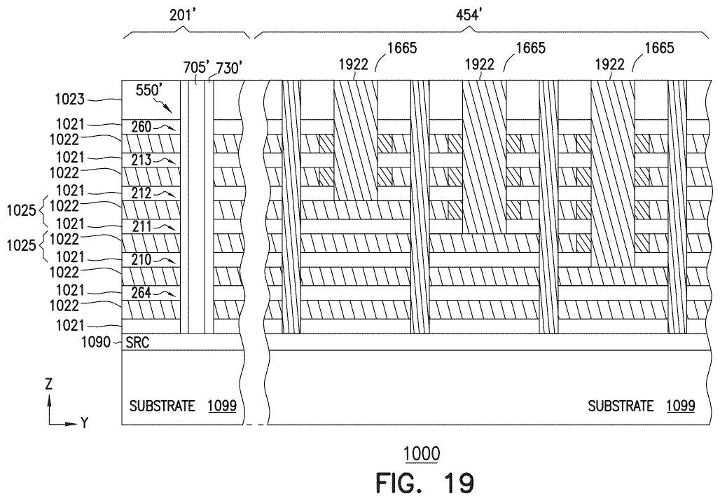

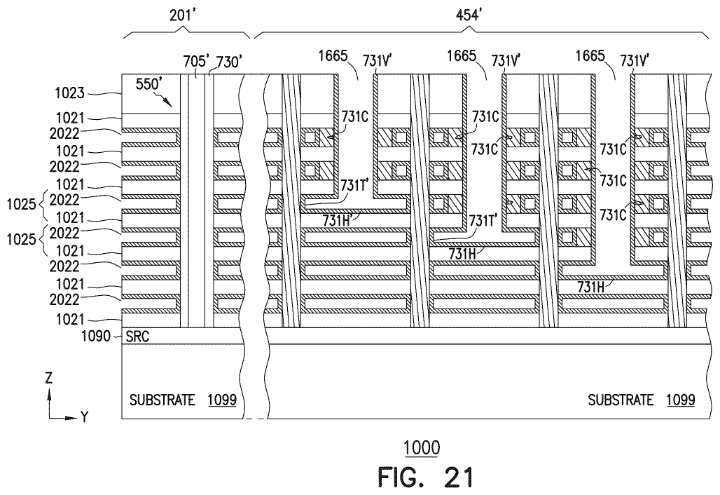

FIG. 15 shows memory device 1000 after dielectric structures 1544 are formed in openings 1144 (labeled in FIG. 14). Forming dielectric structures 1544 can include forming (e.g., filling) a dielectric material in openings 1144. An example of the dielectric material of dielectric structures 1544 can include silicon dioxide. Alternatively, the dielectric material of dielectric structures 1544 can include a material (e.g., different from silicon dioxide) that can be less susceptible to be removed (e.g., etched slower than dielectric materials 1021 and 1022) during processes associated with FIG. 16A in which a portion of dielectric materials 1021 and 1022 is removed (to form contact openings 1665). This allows the dielectric material (or a majority of the dielectric material) of dielectric structures 1544 to remain in memory device 1000 during the processes associated with FIG. 16A in which a portion of dielectric materials 1021 and 1022 is removed (to form contact openings 1665 in FIG. 16A). Further, the dielectric material of dielectric structures 1544 (FIG. 15) can include a material (e.g., different from silicon dioxide) that can remain in memory device 1000 during the processes associated with FIG. 19 in which dielectric materials 1022 are removed (to be replaced with a conductive material (e.g., in FIG. 21) that forms control gates associated with memory cells 210, 211, 212, and 213.

FIG. 16A and FIG. 16B show memory device 1000 after contact openings 1665 are formed. Forming contact openings 1665 can include removing (e.g., etching) a portion of dielectric materials 1021 and 1022 (FIG. 16A) at the locations of contact openings 1665.

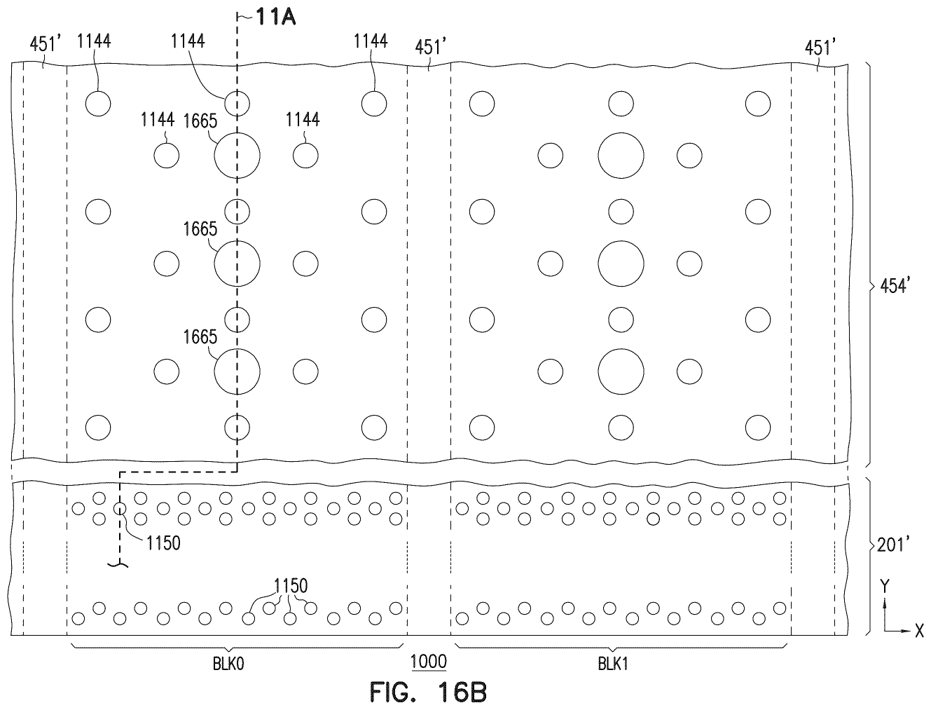

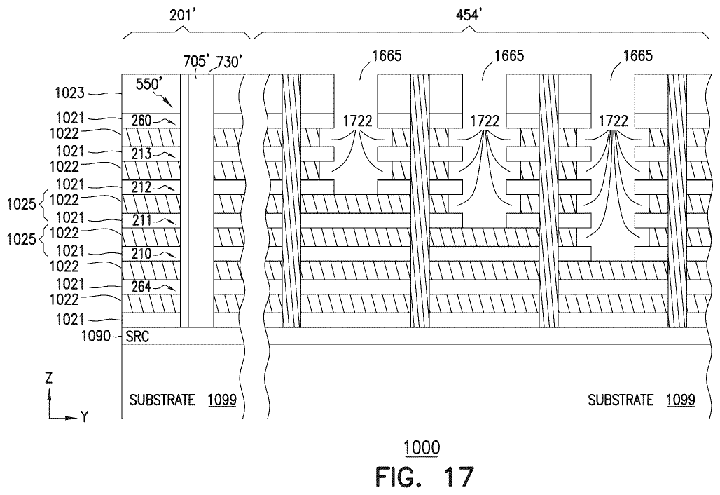

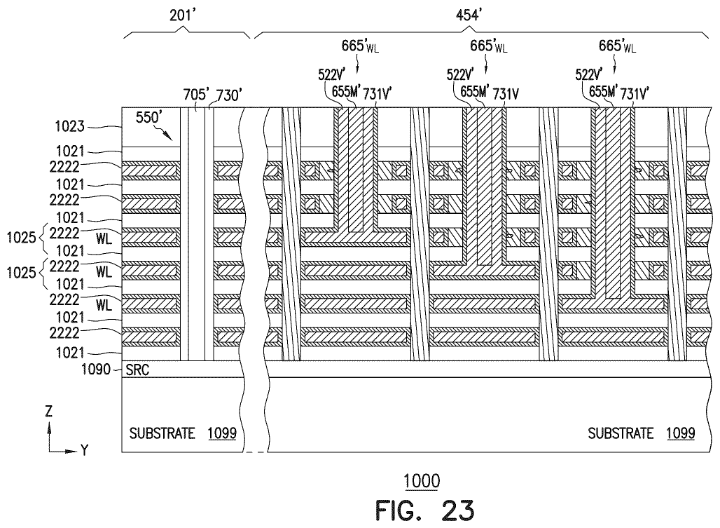

FIG. 17 shows memory device 200 after recesses 1722 are formed in respective dielectric materials 1022. Forming recesses 1722 can include removing respective portions of dielectric materials (e.g., silicon nitride) at locations of recesses 1722, such that part of contact openings 1665 (e.g., side walls of openings) can have the profile (e.g., shape) as shown in FIG. 17. Forming recesses 1722 can increase the effective width of dielectric isolation from one conductive contact to another conductive contact (e.g., conductive contacts 665′_{WL} in FIG. 23) contacting respective levels of conductive materials 2222 (shown in FIG. 23) that form part of the control gates of memory device 1000.

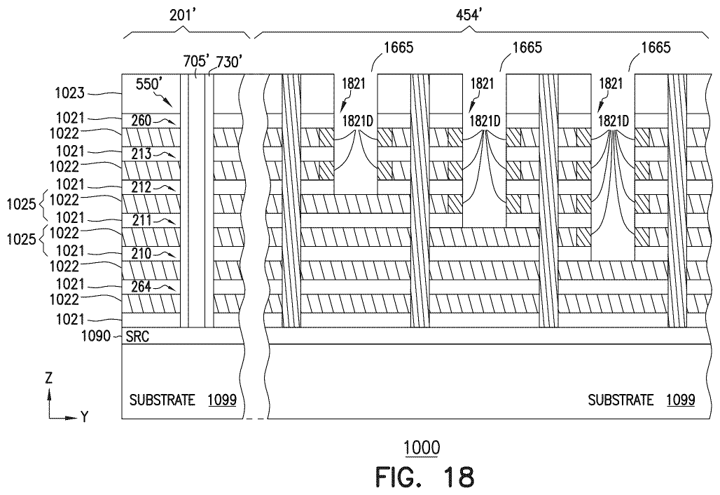

FIG. 18 shows memory device 1000 after a dielectric structures 1821 are formed in respective contact openings 1665. Forming dielectric structures 1821 can include forming dielectric materials (e.g., dielectric portions) 1821D at respective recesses 1722 (FIG. 17). Dielectric materials 1821D can include a dielectric material (e.g., silicon dioxide) that is the same as dielectric material 1021. Dielectric materials 1821D can include a dielectric material (e.g., silicon dioxide) that is different from dielectric material (e.g., silicon nitride) 1022. Dielectric structures 1821 and dielectric materials 1821D can correspond to (e.g., can represent) dielectric structures 721 and dielectric materials 721D, respectively, of memory device 200 of FIG. 7A.

FIG. 19 shows memory device 1000 after a material (or materials) 1922 is formed (e.g., filled) in contact openings 1665. In subsequent processes of forming memory device 1000, material 1922 can be removed from contact openings 1665. Thus, material 1922 can be called a sacrificial material. An example of material 1922 can include silicon nitride or other materials. Forming material 1922 can include forming a material (e.g., silicon nitride) in contact openings 1665. A CMP process can be performed after material 1922 is formed.

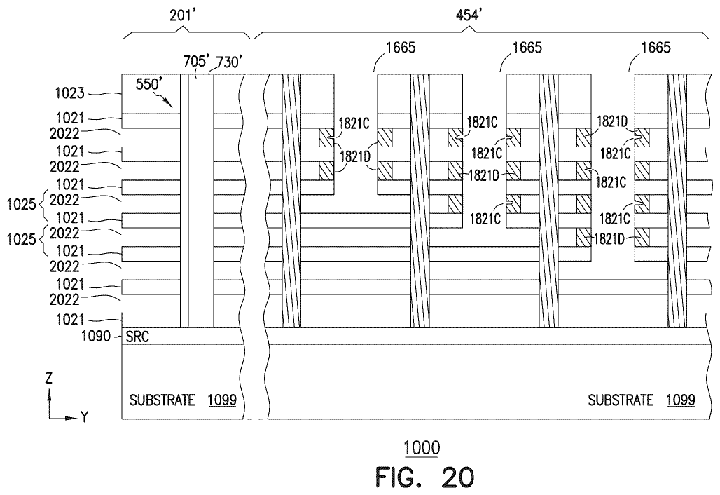

FIG. 20 shows memory device 1000 after dielectric materials 1022 (shown in FIG. 19) are removed (e.g., exhumed) from locations 2022 and material 1922 (shown in FIG. 19) is removed from contact openings 1665. Locations 2022 in FIG. 20 are voids (empty spaces) that were occupied by dielectric materials 1022. In subsequent processes, conductive materials can be formed in locations 2022 to form respective control gates of memory device 1000.

As shown in FIG. 20, dielectric materials 1821D may have cavities 1821C, which may be formed (e.g., unintentionally formed) during the processes of removing material 1922 from contact openings 1665. Cavities 1821C are empty pockets (e.g., voids) in dielectric materials 1821D. In subsequent processes (e.g., FIG. 21) of forming memory device 200, cavities 1821C can be filled with a dielectric material (e.g., a high-k dielectric material). Cavities 1821C are shown in FIG. 20. However, cavities 1821C may also occur (e.g., unintentionally formed) during the processes associated with the processes of forming of dielectric structures 1821 in FIG. 18.

FIG. 21 shows memory device 1000 after dielectric portions 731H′, 731V′, and 731T′ are formed. Forming dielectric portions 731H′, 731V′, and 731T′ can include forming a dielectric material adjacent (e.g., on) the materials (e.g., dielectric materials 1022) at location 2022 (FIG. 20) and adjacent (e.g., on) the materials (e.g., dielectric materials 1821D) at contact openings 1665. The dielectric material of dielectric portions 731H′, 731V′, and 731T′ can be relatively thin (e.g., a thin liner). Thus, dielectric portions 731H′, 731V′, and 731T′ can be called dielectric liners.

Dielectric portion 731V′ and a respective dielectric structure 1821 (labeled in FIG. 18) at a conductive opening 1665 can form multiple dielectric liners of an isolation structure. The multiple dielectric liners include the dielectric material of dielectric portion 731V′ and the dielectric material (e.g., dielectric materials 1821D) of dielectric structure 1821.

Dielectric portions 731H′, 731V′, and 731T′ are formed from a dielectric material (e.g., a high-k dielectric material). Dielectric portions 731H′, 731V′, and 731T′ can form a dielectric liner structure. Dielectric portions 731C, 731H′, 731V′, and 731T′ can be formed concurrently (e.g., formed simultaneously in the same process step). Thus, dielectric portions 731H′, 731V′, and 731T′ can have the same dielectric material. Dielectric portions 731H′, 731V′, and 731T′ can correspond to (e.g., can represent) dielectric portions 731H, 731V, and 731T, respectively, of memory device 200 of FIG. 7A. Thus, the dielectric material (e.g., a high-k dielectric material) of dielectric portions 731H′, 731V′, and 731T′ can be the same as the dielectric material of dielectric portions 731H, 731V, and 731T. Alternatively, dielectric portions 731V′ (or dielectric portions 731H′, 731V′, and 731T′) can be formed from a dielectric material (e.g., silicon dioxide) having a dielectric constant less than a dielectric constant of a high-k dielectric material. However, in memory device 1000, using a high-k dielectric material (e.g., instead of silicon dioxide) for dielectric portions 731V′ (or dielectric portions 731H′, 731V′, and 731T′) can improve isolation of conductive structures (e.g., conductive contacts 665_{WL} and the control gates in FIG. 24) adjacent dielectric portions 731V′. This improved isolation can lead to improved operations (e.g., read or write operations) of the of memory device 1000.

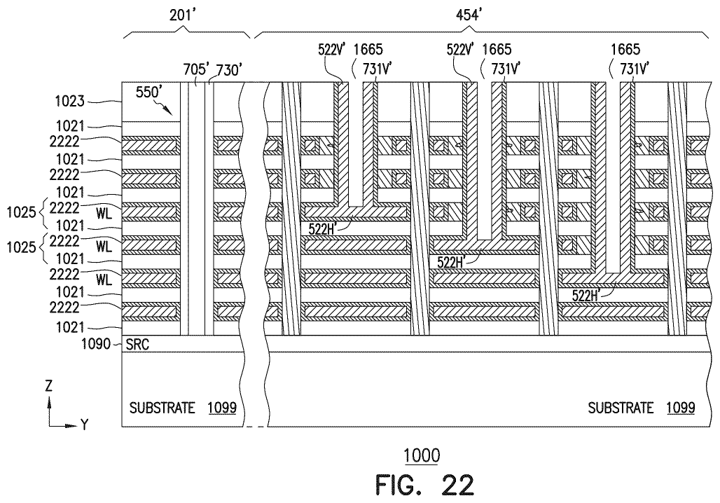

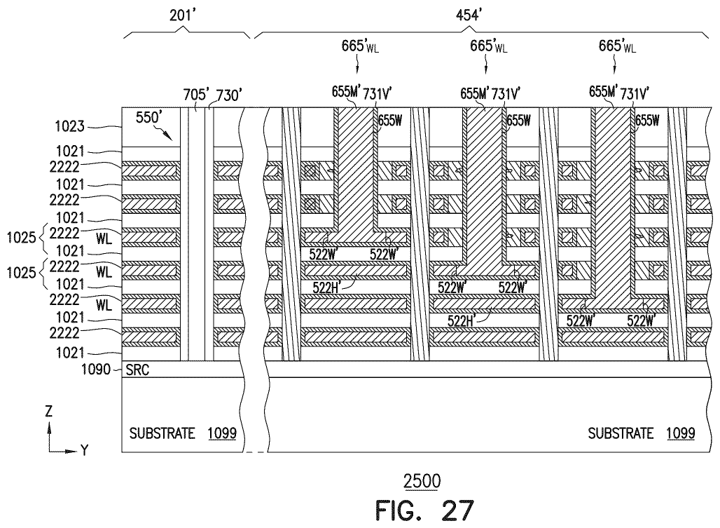

As shown in FIG. 21, cavities 1821C (labeled in FIG. 18) can be filled with dielectric portions 731C. Dielectric portions 731C are formed from the same dielectric material (e.g., a high-k dielectric material) as portions 731H′, 731V′, and 731T′. Dielectric portions 731C can be considered part of dielectric portions 731V′. Filling cavities 1821C with a dielectric material (e.g., a high-k dielectric material) can improve electrical isolation of the conductive contacts (e.g., conductive contacts 665′_{WL} in FIG. 23) formed in contact openings 1665. In contrast, without dielectric portions 731V′ (if dielectric portions 731V′ is not formed), a conductive material (e.g., conductive material of conductive portion 522V′ in FIG. 22 or conductive material 665M′ in FIG. 27) or may fill cavities 1821C. Cavities 1821C filled with a conductive material can negatively affect the electrical isolation of the conductive contacts (e.g., conductive contacts 665′_{WL} in FIG. 23) formed in contact openings 1665.

FIG. 22 shows memory device 1000 after conductive materials (levels of conductive materials) 2222 are formed in locations 2022 (FIG. 21). In FIG. 22, forming conductive materials 2222 can include forming (e.g., filling) a conductive material (or a combination of conductive materials) 2222 in locations 2022 (labeled in FIG. 21) to form conductive portions (e.g., horizontal conductive portions) 522H′. Part of conductive materials 2222 can also be formed in respective contact openings 1665 to form conductive portions (e.g., horizontal conductive portions) 522V′. Conductive portions 522H′ and 522V′ can correspond to conductive portions 522H and 522V of memory device 200 of FIG. 7A. In FIG. 22, conductive portions 522H′ and 522V′ can be concurrently formed (e.g., formed simultaneously in the same process step). Thus, conductive portions 522H′ and 522V′ can have the same conductive material.

Conductive portions 522H′ of conductive materials 2222 are sometimes called levels of conductive materials. In FIG. 22, signals WL can correspond to some of the signals WL0₀, WL1₀, WL2₀, and WL3₀ of memory device 200 FIG. 7A. In FIG. 22, conductive materials 2222 (e.g., conductive portions 522H′) can form part of the control gates (e.g., the control gates associated with signals WL) and select lines (not shown) of memory device 1000 that can be similar to the control gates associated with signals associated with signals WL0₀, WL1₀, WL2₀, and WL3₀ (FIG. 7A) of memory device 200 (FIG. 7A) and the select line associated with signal SGD0₀ and SGD₀ (FIG. 7A) of memory device 200. FIG. 22 shows an example where some of the levels of conductive materials 2222 can form the control gates (e.g., the control gates associated with signals WL). Thus, forming conductive materials 2222 includes forming the control gates and select lines of memory device 1000.

As described above, locations 2022 are locations of dielectric materials 1022 (FIG. 19) that were removed in FIG. 20. Thus, in FIG. 22 forming the control gates (e.g., the control gates associated with signals WL in FIG. 22) and the select lines of memory device 1000 can include replacing the levels of dielectric materials 1022 of FIG. 19 with respective levels of conductive materials (e.g., conductive portions 522H′ of conductive materials 2222) of FIG. 22. Conductive materials 2222 can include a similar material or the same material as conductive materials 522 (FIG. 7A) of memory device 200. Thus, conductive materials 2222 can include a single conductive material (e.g., single metal (e.g., tungsten)) or a combination of different layers of conductive materials. For example, conductive material 2222 can include (e.g., can have multi-layers of) titanium nitride and tungsten, or other conductive materials.

FIG. 23 shows memory device 1000 after conductive contacts 665′_{WL} are formed in contact openings 1665 (labeled in FIG. 22). Forming conductive contacts 665′_{WL} can include forming (e.g., filling) a conductive material 665M′ in contact openings 1665. In FIG. 23, conductive portions 522V′ can form part of respective conductive contacts 665′_{WL}. Conductive material 665M′ can be similar to (or the same as) conductive material 665M of memory device 200 of FIG. 7A. As shown in FIG. 23, the structures of conductive contacts 665′_{WL} are similar to (or the same as) the structures of conductive contacts 665_{WL} of memory device 200 of FIG. 7A. Thus, the structures of conductive contacts 665_{WL} are not described in detail herein.

FIG. 24 shows memory device 1000 after conductive portions 2441 and 2442, data lines 2470, and conductive lines 2456 are formed. Data lines 2470 and signals BL can be similar to data lines 270₀ through 270_{N} and signals BL₀ through BL_{N}, respectively, of memory device 200 in FIG. 4. Conductive lines 2456 can be similar to conductive lines 656 of FIG. 6C. Thus, conductive lines 2456 can have respective lengths in the X-direction like conductive lines 656 of FIG. 6C.

As shown in FIG. 24, conductive portions 2442 can be coupled to respective data lines 2470 (associated with signals BL) and respective pillars (memory cell pillars) 550′. Conductive portions 2441 can be similar to conductive portions 641 of memory device of FIG. 6C. As shown in FIG. 24, conductive portions 2441 can be coupled to respective conductive lines 2456 and respective conductive contacts 665′_{WL}.

The processes of forming memory device 1000 described above with reference to FIG. 10A through FIG. 24 can include other processes to form a complete memory device (e.g., memory device 1000). Such processes are omitted from the above description so as not to obscure the subject matter described herein.

Forming memory device 1000 as described above can provide improvements and benefits to memory device 1000 in comparison to some conventional techniques. For example, additional processes (e.g., implantation) associated with forming contact openings (e.g., like contact openings 1665 in FIG. 16) may be skipped (e.g., eliminated). In another example, relatively inexpensive sacrificial material can be used in some of the processes (e.g., the processes associated with FIG. 19) of forming memory device 1000. In another example, undesirable tier bending (e.g., in the processes associated with FIG. 20) may be reduced or may have insignificant impact on the tier structure of memory device 1000. Further, as described above, forming a dielectric liner (e.g., dielectric portions 731V′ in FIG. 21) in memory device 1000 can also form dielectric portions 731C (FIG. 21) that improve electrical isolation of the conductive contacts (e.g., conductive contacts 665′_{WL} in FIG. 24) of memory device 1000. Memory device 1000 can further have other improvements and benefits similar to those of memory device 200 describe above.

Moreover, as described above, memory device 200 in FIG. 7A can be formed using processes similar to the processes of forming memory device 1000. Thus, as shown in FIG. 7A, the structure of memory device 200 at conductive contacts 665_{WL} and levels of conductive materials 522 in FIG. 7A is similar to the structure of memory device 1000 at conductive contacts 665′_{WL} and levels of conductive materials 2222 in FIG. 24. Further, although FIG. 7A does not show memory device 200 having cavities 1821C (like in FIG. 20) and dielectric portions 731C (like in FIG. 21), memory device 200 of FIG. 7A can also include cavities 1821C filled with dielectric portions 731C. Therefore, in addition to other improvements and benefits described above for memory device 200 of FIG. 7A, memory device 200 in FIG. 7A can also structures and improvements and benefits similar to those of memory device 1000 describe above with reference to FIG. 10A through FIG. 24.

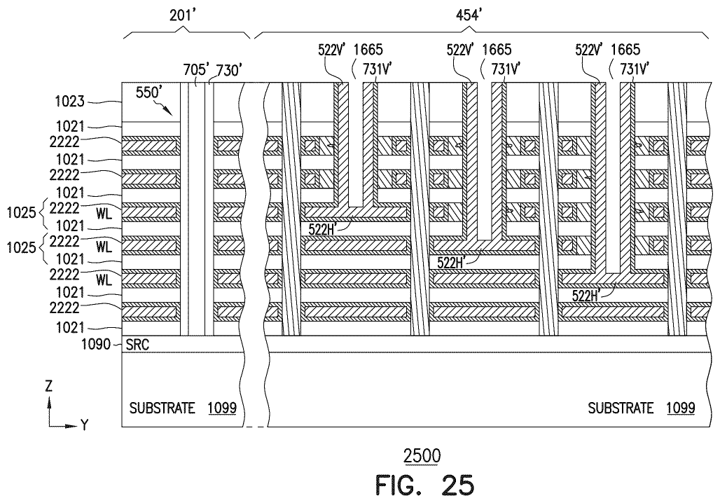

FIG. 25 through FIG. 28 show different views of elements during processes of forming memory device 2500, according to some embodiments described herein. The processes of forming memory device 2500 can be similar to or the same as the processes of forming memory device 1000 (FIG. 10A through FIG. 24). Thus, for simplicity, similar or the same process are not repeated.

FIG. 25 shows elements of memory device 2500 that are the same as those of memory device 1000 shown in FIG. 22. The processes of forming memory device 2500 associated with FIG. 25 can include the processes associated with forming memory device 1000 from FIG. 10A through FIG. 22. For example, like FIG. 22, FIG. 25 shows memory device 2500 after conductive portions 522H′ and 522V′ of respective conductive materials 2222 are formed.

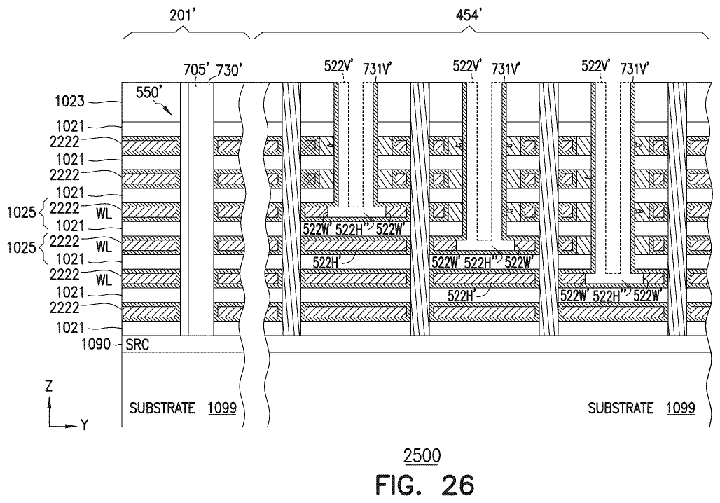

FIG. 26 shows memory device 2500 after conductive portions 522V′ and part of conductive portions 522H′ (e.g., part 522H″ of conductive portions 522H′) are removed. As shown in FIG. 26, conductive portions 522H′ (the remaining conductive portions 522H′) can have side wall 522W′. Side walls (e.g., vertical side walls) 522W′ can correspond to side walls 522W of memory device 800 of FIG. 8A.

FIG. 27 shows memory device 2500 after conductive contacts 665′_{WL} are formed in contact openings 1665 (labeled in FIG. 25). Forming conductive contacts 665′_{WL} can include forming (e.g., filling) a conductive material 665M′ in contact openings 1665. Conductive material 665M′ can be similar to (or the same as) conductive material 665M′ of memory device 1000 formed in FIG. 23. As shown in FIG. 27, conductive material 665M′ can be part of a side wall 655W of a respective conductive contact 665_{WL} and can be adjacent (e.g., can contact) respective dielectric portions 731V′. Conductive material 665M′ can also be adjacent (e.g., can contact) side walls 522W′ of respective conductive portions 522H′ of conductive material 522.

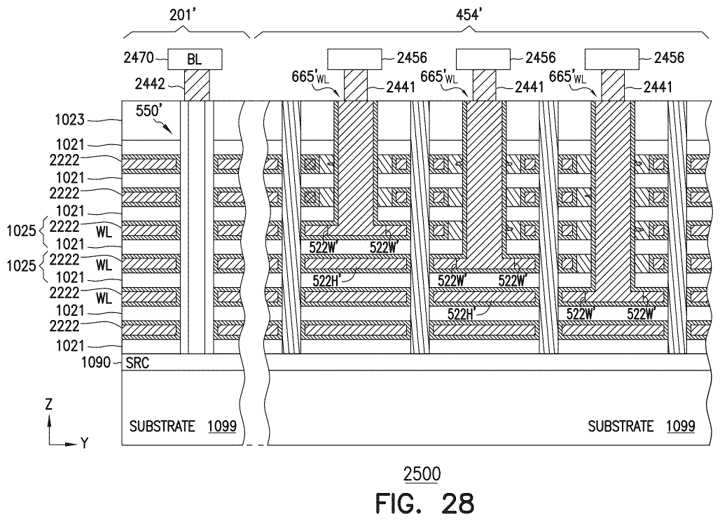

FIG. 28 shows memory device 2500 after elements including conductive portions 2441 and 2442, data lines 2470, and conductive lines 2456 are formed. These elements are similar to or the same as those of memory device 1000 of FIG. 24.

The processes of forming memory device 2500 described above with reference to FIG. 25 through FIG. 28 can include other processes to form a complete memory device (e.g., memory device 2500). Such processes are omitted from the above description so as not to obscure the subject matter described herein.

As described above, memory device 800 in FIG. 8A can be formed using processes similar to the processes of forming memory device 2500. Thus, as shown in FIG. 8A, the structure of memory device 800 at conductive contacts 665_{WL} and levels of conductive materials 522 in FIG. 8A is similar to the structure of memory device 2500 at conductive contacts 665′_{WL} and levels of conductive materials 2222 in FIG. 28.

As shown in FIG. 28, memory device 2500 can include cavities 1821C (not labeled) filled with dielectric portions 731C (not labeled) like memory device 1000 of FIG. 24. In comparison with memory device 800 of FIG. 8A, although FIG. 8A does not show memory device 800 having cavities 1821C and dielectric portions 731C, memory device 800 of FIG. 8A can also include cavities 1821C filled with dielectric portions 731C like memory device 1000 of FIG. 24 or memory device 2500 of FIG. 28. Memory device 2500 can include improvements and benefits similar to those of the memory devices (e.g., memory devices 200, 800, and 1000) described above.

The illustrations of apparatuses (e.g., memory devices 100, 200, 800, 900, 1000, and 2500) and methods (e.g., method of forming memory devices 1000 and 2500) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 800, 900, 1000, and 2500) or a system (e.g., a computer, a cellular phone, or other electronic systems) that includes a device such as any of memory devices 100, 200, 800, 900, 1000, and 2500.

Any of the components described above with reference to FIG. 1 through FIG. 28 can be implemented in a number of ways, including simulation via software. Thus, apparatuses, e.g., memory devices 100, 200, 800, 900, 1000, and 2500 or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 800, 900, 1000, and 2500 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 28 include apparatuses and methods of forming the apparatuses. One of the apparatuses includes levels of dielectric materials interleaved with levels of conductive materials, the levels of conductive materials including a first conductive level and a second conductive level; a memory cell string including a pillar extending in a direction from the first conductive level to the second conductive level, the second conductive level including a side wall; a conductive contact extending in the direction from the first conductive level to the second conductive level and contacting the second conductive level; a first dielectric material between the first conductive level and the conductive contact, the first dielectric material having a first dielectric constant; and a second dielectric material between the first dielectric material and the conductive contact, the second dielectric material having a second dielectric constant, wherein the second dielectric constant is greater than the first dielectric constant. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
levels of dielectric materials;
levels of conductive materials interleaved with the levels of dielectric materials, the levels of conductive materials including a first conductive level and a second conductive level;
a memory cell string including a pillar extending in a direction from the first conductive level to the second conductive level, the second conductive level including a side wall;
a conductive contact extending in the direction from the first conductive level to the second conductive level and contacting the second conductive level;
a first dielectric material between the first conductive level and the conductive contact, the first dielectric material having a first dielectric constant; and
a second dielectric material between the first dielectric material and the conductive contact, the second dielectric material having a second dielectric constant, wherein the second dielectric constant is greater than the first dielectric constant.

2. The apparatus of claim 1, wherein the second dielectric constant is greater than a dielectric constant of silicon dioxide.

3. The apparatus of claim 1, wherein the first dielectric material includes silicon dioxide.

4. The apparatus of claim 1, wherein the second conductive level includes a side wall, and the conductive contact contacts the side wall of the second conductive level.

5. The apparatus of claim 1, wherein:
the first conductive level includes a first edge;
the second conductive level includes a second edge; and
the conductive contact is between the pillar of the memory cell string and the first edge, and between the pillar of the memory cell string and the second edge.

6. The apparatus of claim 1, wherein the first dielectric material includes a cavity, and the cavity includes a dielectric material different from the first dielectric material.

7. The apparatus of claim 1, further comprising an additional conductive contact extending in the direction from the first conductive level to the second conductive level, and the additional conductive contacting the first conductive level.

8. The apparatus of claim 7, further comprising a dielectric pillar between the conductive contact and the additional conductive contact, the dielectric pillar extending in the direction from the first conductive level to the second conductive level.

9. The apparatus of claim 8, further comprising an additional dielectric pillar extending in the direction from the first conductive level to the second conductive level, wherein the additional conductive contact is between the dielectric pillar and the additional dielectric pillar.

10. The apparatus of claim 1, wherein the second conductive level is part of a word line associated with the memory cell string.

11. An apparatus comprising:
a first tier including first memory cells and a first control gate associated with the first memory cells;
a second tier including second memory cells and a second control gate associated with the second memory cells;
a conductive contact extending in a direction from the first control gate to the second control gate and contacting the second control gate;
a first dielectric material adjacent the first control gate;
a second dielectric material adjacent the first dielectric material; and
a third dielectric material between the second dielectric material and the conductive contact.

12. The apparatus of claim 11, wherein:
the first dielectric material has a first dielectric constant;
the second dielectric material has a second dielectric constant; and
the third dielectric material has a third dielectric constant, wherein the second dielectric constant is less than each of the first dielectric constant and the second dielectric constant.

13. The apparatus of claim 12, wherein the third dielectric constant is greater than a dielectric constant of silicon dioxide.

14. The apparatus of claim 11, wherein one of the first memory cells and one of the second memory cells is associated with a memory cell pillar, wherein:
the first control gate includes a first edge;
the second control gate includes a second edge; and
the conductive contact is between the memory cell pillar and the first edge, and between the memory cell pillar and the second edge.

15. The apparatus of claim 11, further comprising an additional conductive contact extending in the direction from the first control gate to the second control gate, wherein the first control gate includes a side wall, and the additional conductive contact includes a second portion adjacent the side wall of the first control gate.

16. The apparatus of claim 15, further comprising a dielectric pillar between the conductive contact and the additional conductive contact, the dielectric pillar extending in the direction from the first control gate to the second control gate.

17. A method comprising:
forming levels of first materials;
forming levels of second materials interleaved with the levels of first materials;
forming memory cells including forming a pillar associated with the memory cells through the levels of first materials and the levels of second materials;
forming an opening in the levels of first materials and the levels of second materials;
forming a dielectric liner in the opening, the dielectric liner having a dielectric constant greater than a dielectric constant of silicon dioxide; and
forming a conductive contact in the opening, wherein the conductive contact is separated from the levels of first materials by the dielectric liner.

18. The method of claim 17, wherein:
the levels of first materials include a first level having a first edge;
the levels of second materials include a second level having a second edge; and
the conductive contact is formed such that the conductive contact is between the pillar associated with the memory cells and the first edge, and such that the conductive contact is between the pillar associated with the memory cells and the second edge.

19. The method of claim 17, wherein forming the conductive contact includes forming a first conductive portion adjacent the dielectric liner, and forming a conductive material adjacent the first conductive portion.

20. The method of claim 17, further comprising:
forming a dielectric structure between the dielectric liner and a portion of the levels of first materials, wherein the dielectric structure and the dielectric liner have different dielectric materials.
